(19) United States
(12) Patent Application Publication
(10) Pub. No.: US 2026/0262293 A1
(43) Pub. Date: Sep. 3, 2026

(54) ARRAY SUBSTRATE, DISPLAY PANEL, DISPLAY DEVICE AND REPAIR METHOD

(71) Applicants: CHENGDU BOE DISPLAY SCI-TECH CO., LTD., Chengdu, Sichuan (CN); BOE Technology Group Co., Ltd., Beijing (CN); Beijing BOE Technology Development Co., Ltd., Beijing (CN)

(72) Inventors: Xinping SHI, Beijing (CN); Toshifumi YAGI, Beijing (CN); Guidong YANG, Beijing (CN); Feng XIAO, Beijing (CN); Gang CHEN, Beijing (CN); Wei ZHU, Beijing (CN); Tao LIU, Beijing (CN); Yue GUAN, Beijing (CN); Yu DENG, Beijing (CN)

(21) Appl. No.: 18/715,231

(22) PCT Filed: Aug. 29, 2023
(86) PCT No.: PCT/CN2023/115603

§ 371 Date: May 31, 2024

(51) Int. Cl. H10D 86/40; G02F 1/1362; G02F 1/1368; H10D 86/60

(52) U.S. Cl. CPC H10D 86/443; G02F 1/136227; G02F 1/13624; G02F 1/136286; G02F 1/1368; H10D 86/60

(57) ABSTRACT

An array substrate includes: multiple gate line groups, multiple data lines, multiple transistors, multiple pixel electrode groups and multiple first common lines. The transistor include a first electrode and a second electrode, and a part of an orthographic projection of the second electrode on a substrate is located between orthographic projections of two gate lines of a same gate line group on the substrate. Each pixel electrode group includes: two pixel electrodes distributed in a first direction. An orthographic projection of the first common line on the substrate is located between the orthographic projections of the two gate lines of the same gate line group on the substrate, and at least part of the orthographic projection of the first common line on the substrate overlaps with at least part of the orthographic projection of the second electrode of the transistor on the substrate.

### CROSS REFERENCE TO RELATED APPLICATIONS

This application is a national phase entry under 35 U.S.C. § 371 of International Application No. PCT/CN2023/115603, filed on Aug. 29, 2023, the entire content of which is incorporated herein by reference.

### TECHNICAL FIELD

The disclosure relates to the field of semiconductors technology, in particular to an array substrate, a display panel, a display device and a repair method.

### BACKGROUND

A thin film transistor-liquid crystal display (TFT-LCD) has multiple commonly used display modes, such as a twisted nematic (TN) display mode, a vertically alignment (VA) display mode, a fringe field switching (FFS) display mode, and an in-plane switching (IPS) display mode. The VA mode has the advantages of better dark performance and better contrast compared to other display modes.

### SUMMARY

Embodiments of the disclosure provide an array substrate, a display panel, a display device and a repair method. The array substrate includes: a substrate; a plurality of gate line groups, disposed on a side of the substrate and extending in a first direction, where each gate line group includes two gate lines extending in the first direction; a plurality of data lines extending in a second direction, where the second direction intersects with the first direction; a plurality of transistors, where each transistor includes: a first electrode electrically connected with the data line, and a second electrode; where a part of an orthographic projection of the second electrode of the transistor on the substrate is located between orthographic projections of two gate lines of a same gate group on the substrate; a plurality of pixel electrode groups, where an orthographic projection of at least a part of the pixel electrode group on the substrate is located in a region formed due to intersection of the gate line groups and the data lines; and each pixel electrode group includes: two pixel electrodes distributed in the first direction; and a plurality of first common lines, where an orthographic projection of the first common line on the substrate is located between the orthographic projections of the two gate lines of the same gate line group on the substrate, and at least part of the orthographic projection of the first common line on the substrate overlaps with at least part of the orthographic projection of the second electrode of the transistor on the substrate.

In some embodiments, the pixel electrode includes a pixel electrode body and a pixel electrode lapping portion extending from an end of the pixel electrode body; where a part of an orthographic projection of the pixel electrode lapping portion on the substrate is located between the orthographic projections of the two gate lines of the same gate line group on the substrate; and the part of the orthographic projection of the pixel electrode lapping portion on the substrate overlaps with at least part of the orthographic projection of the second electrode of the transistor on the substrate.

In some embodiments, the pixel electrode lapping portion includes: a first sub-lapping portion extending in the second direction and a second sub-lapping portion extending in the first direction; one end of the first sub-lapping portion is electrically connected with the pixel electrode body, and the other end of the first sub-lapping portion is electrically connected with the second sub-lapping portion; and an orthographic projection of the second sub-lapping portion on the substrate is located between the orthographic projections of the two gate lines of the same gate line group on the substrate.

In some embodiments, the two pixel electrodes of a same pixel electrode group are electrically connected with a same data line through the transistor; and in the same pixel electrode group, second sub-lapping portions of the two pixel electrodes extend from corresponding first sub-lapping portions towards a side of the same data line electrically connected with the two pixel electrodes.

In some embodiments, two second sub-lapping portions of two pixel electrodes adjacent in the second direction extend in opposite directions from the corresponding first sub-lapping portions.

In some embodiments, at least two second sub-lapping portions adjacent to each other in the first direction have at least parts symmetrical to each other with respect to a first axis; where the first axis is located between the adjacent pixel electrodes and extending in the second direction.

In some embodiments, the plurality of transistors includes: first transistors and second transistors; in the same pixel electrode group, one of the pixel electrodes is electrically connected with the data line through the first transistor, and the other one of the pixel electrodes is electrically connected with the data line through the second transistor; and for the first transistor and the second transistor which are electrically connected with the same pixel electrode group, a second electrode of the first transistor and a second electrode of the second transistor are symmetrical with respect to a second axis; where the second axis passes through a center of the pixel electrode and extending in the first direction.

In some embodiments, for the first transistor and the second transistor which are electrically connected with the same pixel electrode group, the second electrode of the first transistor and the second electrode of the second transistor are both located between the first axis and the data line electrically connected with the two pixel electrodes.

In some embodiments, two second electrodes which are at least partially adjacent in the second direction are symmetrical with respect to the second axis.

In some embodiments, the second electrode of the transistor includes: a first portions extending in the second direction, and a second portion connected with the first portion and extending in the first direction; and first portions of two second electrodes which are at least partially adjacent in the second direction both extend from corresponding second portions towards a side of a pixel electrode body electrically connected with the transistors.

In some embodiments, first portions of two second electrodes which are at least partially adjacent in the first direction extend in opposite directions from corresponding second portions.

In some embodiments, second portions of two second electrodes which are at least partially adjacent in the first direction are symmetrical with respect to the first axis.

In some embodiments, the transistor further includes: an active pattern; where the active pattern includes: a first active outer edge and a second active outer edge extending in the second direction; in a same transistor, an orthographic projection of the second active outer edge on the substrate is located on a side of the first active outer edge away from the data line connected with the transistor; the first electrode of the transistor includes: a first portion extending in the second direction, and a second portion for connecting the first portion with the data line; and at least part of the orthographic projection of the first active outer edge on the substrate coincides with at least part of an orthographic projection of an outer edge of the first portion of the first electrode at a side of the first portion of the first electrode away from the first portion of the second electrode on the substrate; and at least part of the orthographic projection of the second active outer edge on the substrate coincides with at least part of an orthographic projection of an outer edge of the first portion of the second electrode at a side of the first portion of the second electrode away from the first portion of the first electrode on the substrate.

In some embodiments, the array substrate further includes: a first insulating layer between a layer where the pixel electrode groups are located and a layer where second electrodes of the transistors are located; where the first insulating layer includes first vias, and the pixel electrode lapping portions are electrically connected with the second electrodes of the transistors through the first vias.

In some embodiments, at least part of an orthographic projection of the first common line on the substrate overlaps with at least part of an orthographic projection of the first via on the substrate.

In some embodiments, the array substrate further includes: a color resistor layer located at a side of a layer where the pixel electrodes are located facing the substrate; where the first insulating layer includes the color resistor layer.

In some embodiments, the array substrate further includes: a plurality of first spacers and a plurality of second spacers; where a length of the first spacer in a direction perpendicular to the substrate is greater than a length of the second spacer in the direction perpendicular to the substrate; and a shape of an orthographic projection of the first spacer on the substrate is different from a shape of an orthographic projection of the second spacer on the substrate.

In some embodiments, a maximum length of the second spacer in the second direction is greater than a maximum length of the first spacer in the second direction.

In some embodiments, a distribution density of the second spacers is greater than a distribution density of the first spacers.

In some embodiments, the first common line includes: a first sub common line portion and a second sub common trace portion arranged in the first direction; at least part of an orthographic projection of the first sub common line portion on the substrate overlaps with at least part of the orthographic projection of the data line on the substrate; at least part of orthographic projection of the second sub common line portion on the substrate overlaps with at least part of the orthographic projection of the pixel electrode lapping portion on the substrate; and a maximum length of the first sub common line portion in the second direction is smaller than a maximum length of the second sub common line portion in the second direction.

In some embodiments, the array substrate further includes: a first conductive layer located at a side of the data lines facing away from the substrate; where the first conductive layer includes: a plurality of first lines extending in the second direction, and a second line electrically connected with the first lines and extending in the first direction; the second line is disconnected at a position intersecting with the pixel electrode lapping portion; and at least part of an orthographic projection of the first line on the substrate overlaps with at least part of the orthographic projection of the data line on the substrate, and at least part of an orthographic projection of the second line on the substrate overlaps with at least part of the orthographic projection of the gate line on the substrate.

In some embodiments, the second line includes: a plurality of second line sub portions distributed sequentially in the first direction; the second line sub portions are electrically connected with the first lines; and the first conductive layer further includes: third lines extending in the second direction; and an orthographic projection of the third line on the substrate is located between orthographic projections of the two pixel electrodes of the pixel electrode group on the substrate; and one end of the third line is electrically connected with the second line sub portion on one side of the pixel electrode, and the other end of the third line is connected with the second trace sub portion on the other side of the pixel electrode and connected with an adjacent first line.

In some embodiments, the orthographic projection of the third line on the substrate does not overlap with the orthographic projection of the pixel electrode lapping portion on the substrate.

In some embodiments, a part of the orthographic projection of the second line on the substrate is located at a gap between the gate line and the pixel electrode.

In some embodiments, the array substrate further includes: a display region and a non-display region located on a periphery of the display region; where the first conductive layer further includes a fourth line located in the non-display region and extending in the first direction, and the fourth line has a plurality of first hollowed-out structures.

In some embodiments, the first conductive layer further includes a transfer portion located on a side of the fourth line away from the display region, and the transfer portion includes a plurality of second hollowed-out structures.

In some embodiments, a maximum length of the first hollowed-out structure in the second direction is greater than a maximum length of the first hollowed-out structure in the first direction; and a maximum length of the second hollowed-out structure in the second direction is greater than a maximum length of the second hollowed-out structure in the first direction.

In some embodiments, the maximum length of the first hollowed-out structure in the first direction is smaller than or equal to a minimum spacing between the pixel electrode and the first line in the first direction; and the maximum length of the second hollowed-out structure in the first direction is smaller than or equal to the minimum spacing between the pixel electrode and the first line in the first direction.

In some embodiments, the first conductive layer is a same layer as the pixel electrodes.

Embodiments of the disclosure further provide a display panel, including the array substrate according to the embodiments of the disclosure, and further including: a counter substrate opposite to the array substrate, where the counter substrate is provided with a common electrode layer.

Embodiments of the disclosure further provide a display device, including the display panel according to the embodiments of the disclosure.

Embodiments of the disclosure further provide a method of repairing the array substrate according to the embodiments of the disclosure, including: detecting the array substrate; and based on determining that a pixel emits light abnormally, electrically connecting a transistor electrically connected with a pixel electrode in the pixel to the first common line.

In some embodiments, the electrically connecting the transistor electrically connected with the pixel electrode in the pixel to the first common line, includes: electrically connecting a second electrode of the transistor to the first common line at a position where a first via is located.

### BRIEF DESCRIPTION OF FIGURES

FIG. 1A is a first one of top views of an array substrate provided in embodiments of the disclosure.

FIG. 1B is a schematic single-layer diagram of a gate line layer in FIG. 1A.

FIG. 1C is a schematic single-layer diagram of an active layer in FIG. 1A.

FIG. 1D is a schematic single-layer diagram of a data line layer in FIG. 1A.

FIG. 1E is a schematic single-layer diagram of a pixel electrode layer in FIG. 1A.

FIG. 1F is a sectional view taken along a dashed line A-A′ in FIG. 1A.

FIG. 1G is a sectional view taken along a dashed line B-B′ in FIG. 1A.

FIG. 1H is a first one of sectional views taken along a dashed line C-C′ in FIG. 1A.

FIG. 1I is an enlarged view corresponding to a dashed box S1 in FIG. 1A.

FIG. 1J is a schematic diagram of FIG. 1I after weakening treatment.

FIG. 1K is a second one of sectional views taken along a dashed line C-C′ in FIG. 1A.

FIG. 2A is a first one of schematic diagrams of a first spacer and a second spacer provided in embodiments of the disclosure.

FIG. 2B is a second one of schematic diagrams of a first spacer and a second spacer provided in embodiments of the disclosure.

FIG. 3A is a second one of top views of an array substrate provided in embodiments of the disclosure.

FIG. 3B is a schematic single-layer diagram of a pixel electrode layer in FIG. 3A.

FIG. 4 is an equivalent circuit diagram provided in embodiments of the disclosure.

FIG. 5 is a schematic diagram showing liquid crystal alignments in different regions provided in embodiments of the disclosure.

FIG. 6 is a first schematic diagram illustrating a principle of the generation of a shaking pattern.

FIG. 7 is a second schematic diagram illustrating a principle of the generation of a shaking pattern.

FIG. 8 is a schematic diagram of a shaking pattern.

FIG. 9 is a schematic flow chart of a method for repairing an array substrate provided in embodiments of the disclosure.

FIG. 10 is a schematic structural diagram of a display panel provided in embodiments of the disclosure.

### DETAILED DESCRIPTION

In order to make the objective, technical solutions and advantages of embodiments of the disclosure clearer, the technical solutions of the embodiments of the disclosure will be described clearly and completely with reference to accompanying drawings of the embodiments of the disclosure. Apparently, the described embodiments are some of the embodiments of the disclosure, not all of them. On the basis of the described embodiments of the disclosure, all other embodiments obtained by those ordinarily skilled in the art without inventive efforts fall within the scope of protection of the disclosure. The implementations may be implemented in multiple different forms. The ordinarily skilled in the art can easily understand the fact that modes and content can be transformed into one or more forms without departing from the purpose and scope of the disclosure. Therefore, the disclosure should not be interpreted as only limited to the content recorded in the following implementations. The embodiments in the disclosure and features in the embodiments may be arbitrarily combined with each other in the case of no conflict.

Unless otherwise indicated, technical or scientific terms used in the disclosure shall have the usual meanings understood by those ordinarily skilled in the art to which the disclosure pertains. “First”, “second” and similar words used in the disclosure do not indicate any order, quantity or importance, but are only used to distinguish different components. “Including” or “containing” and similar words, mean that an element or item preceding the word encompasses an element or item listed after the word and the equivalent thereof, without excluding other elements or items. “Connection” or “coupling” and similar words are not limited to a physical or mechanical connection, but may include an electrical connection, whether direct or indirect.

As used here, “approximately” or “substantially the same” includes a stated value and implies an acceptable deviation range for a specific value, as determined by the ordinarily skilled in the art, taking into account the measurement in question and the errors related to the measurement of a specific quantity (i.e., limitations of a measurement system). For example, “substantially the same” may mean that a difference relative to the stated value is within one or more standard deviation ranges, or within a range of ±30%, 20%, 10%, and 5%. In this specification, “roughly the same” may refer to a situation where the values differ by no more than 10%.

In the accompanying drawings, for clarity, thicknesses of a layer, a film, a panel, a region, and the like has been enlarged. In this specification, an exemplary implementation is described by referring to a cross-sectional diagram as a schematic diagram of an idealized implementation. In this way, deviations from the shape of the diagram will be anticipated as a result of manufacturing techniques and/or tolerances, for example. Therefore, the implementation described herein should not be construed as being limited to the specific shape of the region as shown in this specification, but should include deviations in shape caused by, for example, manufacturing. For example, a region depicted or described as flat may typically have rough and/or non-linear features. In addition, a sharp corner depicted may be circular. Therefore, the region shown in the figure is essentially schematic, and their shapes are not intended to illustrate the precise shape of the region, nor are they intended to limit the scope of the present claims.

In this specification, for convenience, words and phrases indicating orientation or positional relationship, such as “middle”, “upper”, “lower”, “front”, “rear”, “vertical”, “horizontal”, “top”, “bottom”, “inside” and “outside” are used to describe the positional relationship of constituent elements with reference to the accompanying drawings, are only to facilitate description of this specification and description simplification, rather than indicating or implying that the indicated apparatus or element must have a specific orientation or be constructed and operated in the specific orientation, and therefore cannot be understood as limitation to the disclosure. The positional relationship of the constituent elements is appropriately changed according to the direction in which the constituent elements are described. Therefore, it is not limited to the words and phrases described in the specification, and can be appropriately replaced according to the situation.

In the specification, unless otherwise indicated and limited, the terms “installed”, “linked” and “connected” should be construed in a broad sense. For example, it may be a fixed connection, or a detachable connection, or an integral connection; it may be a mechanical connection, or an electrical connection; and it may be a direct connection, or an indirect connection through an intermediate piece, or internal communication between two elements. Those skilled in the art may understand the meaning of the above terms in the disclosure according to the situation.

In the specification, “electrical connection” includes the situation where constituent elements are connected through an element with some electrical action. There is no specific limitation on “elements with some electrical action” as long as it can transmit electrical signals between constituent elements that are connected. Examples of “elements with some electrical action” include not only electrodes and wiring but also switching elements such as transistors, resistors, inductors, capacitors, and other elements with one or more functions.

In the specification, a transistor refers to an element including at least three terminals of a gate electrode (a gate), a drain electrode and a source electrode. The transistor has a channel region between the drain electrode (a drain electrode terminal, a drain region or the drain) and the source electrode (a source electrode terminal, a source region or the source), and a current can flow through the drain electrode, the channel region and the source electrode. In the disclosure, the channel region refers to a region through which the current mainly flows.

Additionally, the gate of the transistor may be referred to as a control electrode. Functions of the “source electrode” and the “drain electrode” are interchanged sometimes when transistors of opposite polarities are used or when a direction of the current changes during circuit operation. Therefore, in the specification, the “source electrode” and the “drain electrode” may be interchanged.

In the specification, “parallel” refers to a state where an angle formed by two straight lines is greater than −10° and smaller than 10°, and therefore may include a state where the angle is greater than −5° and smaller than 5°. In addition, “vertical” refers to a state where the angle formed by the two straight lines is greater than 80° and smaller than 100°, and therefore may include a state where the angle is greater than 85° and smaller than 95°.

In this specification, a triangle, a rectangle, a trapezoid, a pentagon, or a hexagon are not strictly defined and may be approximated as the triangle, the rectangle, the trapezoid, the pentagon, or the hexagon. There may be some small deformations caused by tolerances, and there may be features such as chamfers, curved edges, and deformations.

In the specification, a “film” and a “layer” may be interchanged. For example, a “conductive layer” may be replaced with a “conductive film” in some cases. Similarly, an “insulating film” may be replaced with an “insulating layer” in some cases.

To keep the following description of embodiments of the disclosure clear and concise, detailed descriptions of known functions and known components have been omitted.

In a process of weakening the pixel for repair, it is necessary to fuse the transistor drain with a common line, so that a potential of the pixel electrode is held at a common (Vcom) potential and is displayed as a dark spot. During the conventional pixel design, this weakening via is located in a center of a pixel opening region, and according to process requirements, a metal area (the transistor drain) is relatively large, which will seriously affect a pixel aperture ratio. In a case of a dual gate structure, compared to a conventional single gate structure, one gate line is added, and the pixel aperture ratio is further decreased. Combining a color filter on array (COA) technology, a color resistor layer needs to be perforated at the position corresponding to the via. After perforated, the color resistor layer needs to be blocked by a light blocking layer. Therefore, the weakening via cannot be arranged in the center of the pixel opening region. To maximize the pixel aperture ratio, the via needs to be moved as close to the gate line as possible, the weakening vias corresponding to the transistors at an upper side and a lower side of the same pixel electrode are configured separately, and the aperture ratio will be lost again.

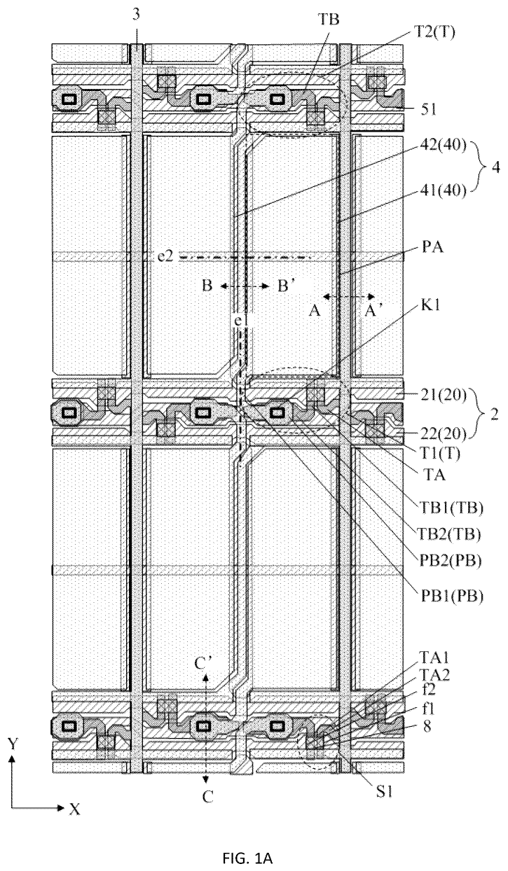

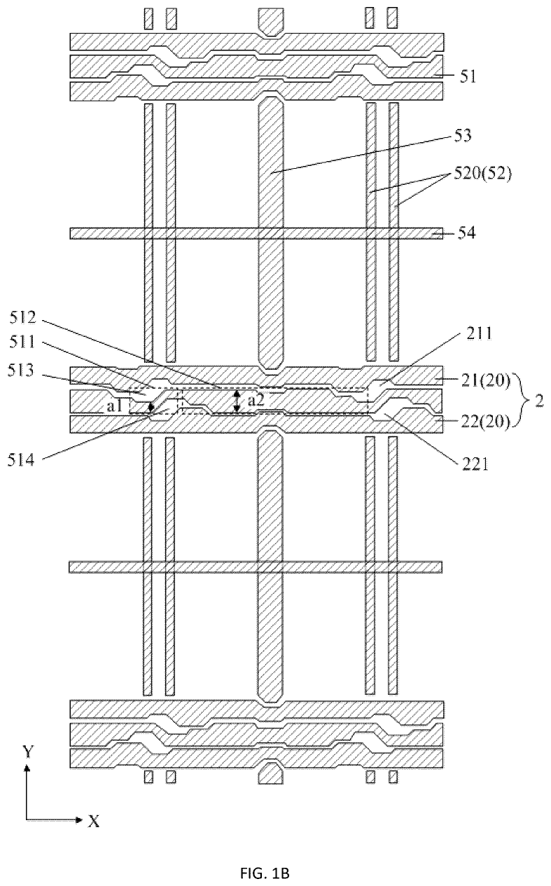

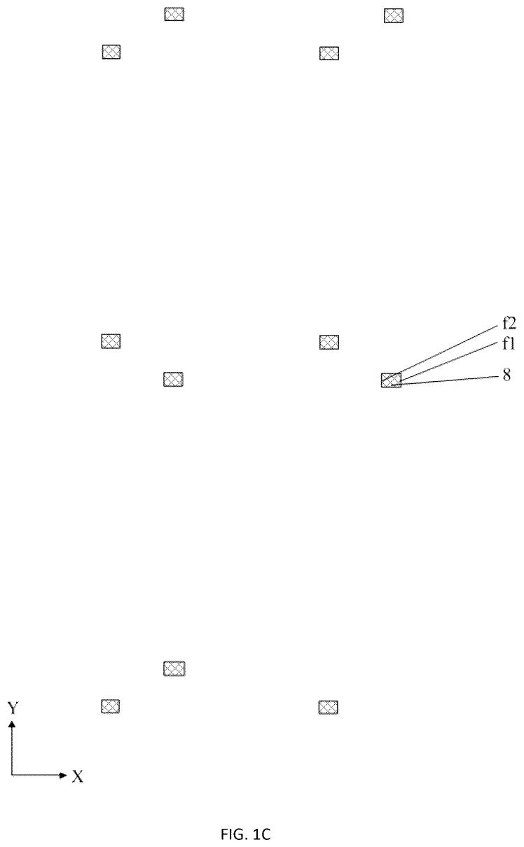

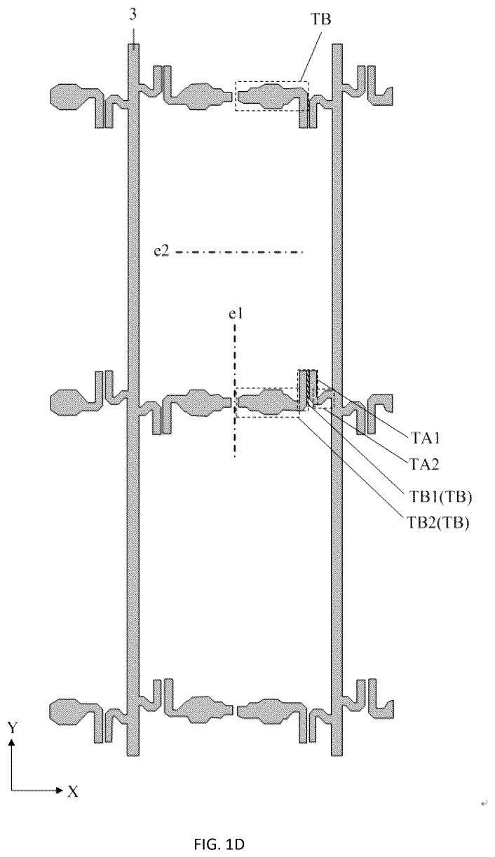

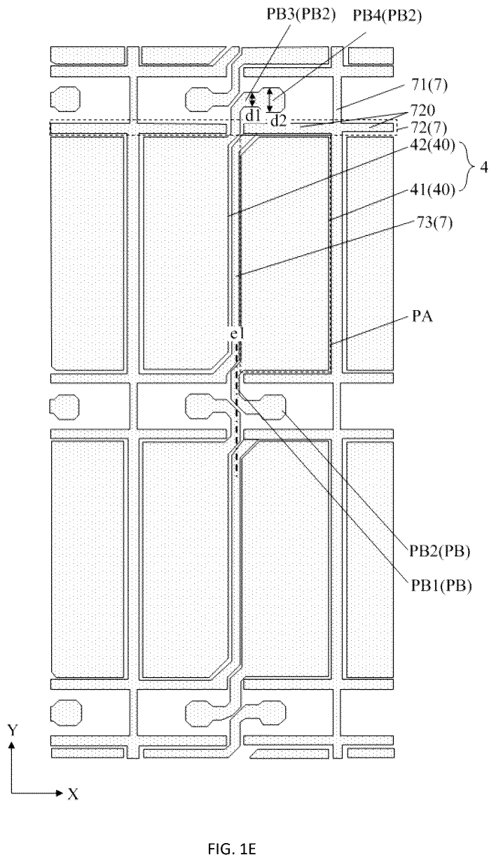

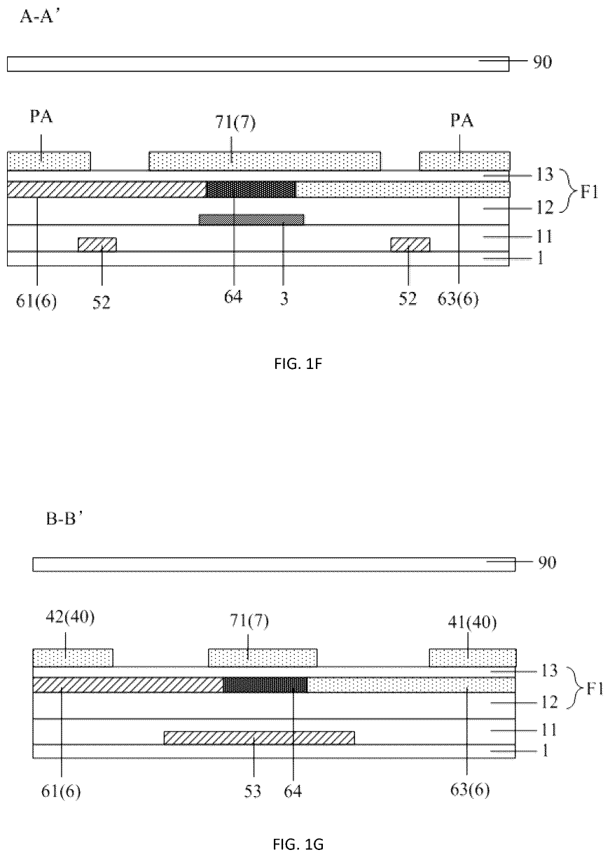

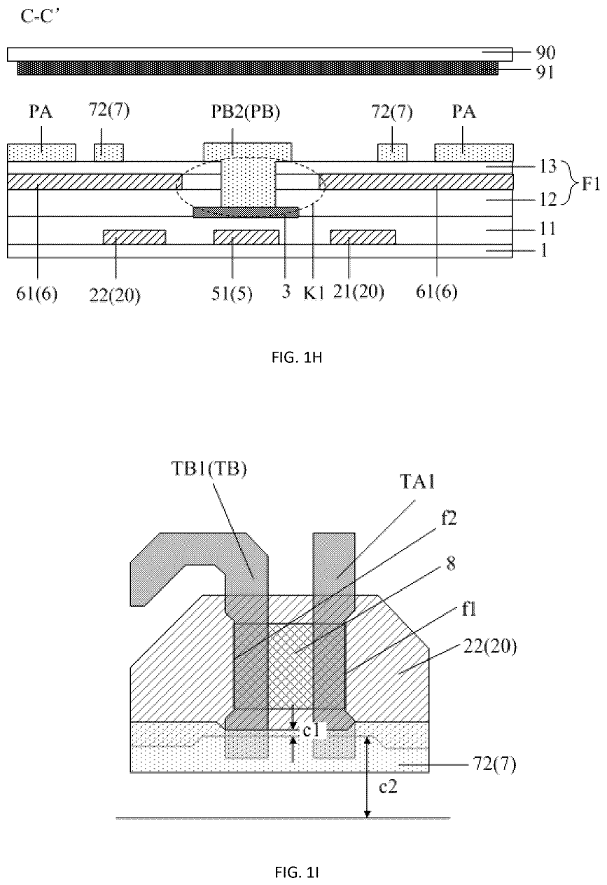

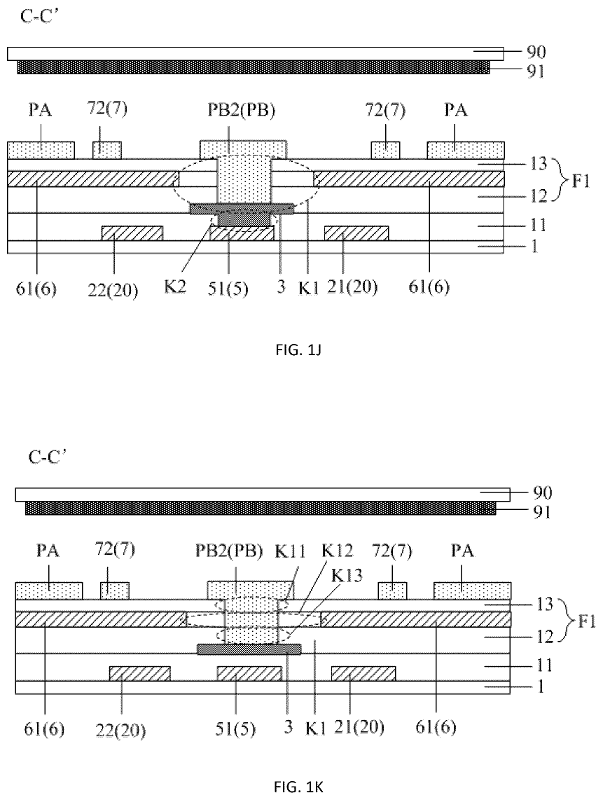

In view of this, referring to FIG. 1A to FIG. 1H. FIG. 1A is a first one of top views of an array substrate provided in embodiments of the disclosure. FIG. 1B is a schematic single-layer diagram of a gate line layer in FIG. 1A. FIG. 1C is schematic single-layer diagram of an active layer in FIG. 1A. FIG. 1D is a schematic single-layer diagram of a data line layer in FIG. 1A. FIG. 1E is a schematic single-layer diagram of a pixel electrode layer in FIG. 1A. FIG. 1F is a sectional view taken along a dashed line A-A′ in FIG. 1A. FIG. 1G is a sectional view taken along a dashed line B-B′ in FIG. 1A. FIG. 1H is a first one of sectional views taken along a dashed line C-C′ in FIG. 1A. Embodiments of the disclosure provide an array substrate, including:
a substrate 1;
a plurality of gate line groups 2, disposed on a side of the substrate 1 and extending in a first direction X; where the gate line group includes: two gate lines 20 extending in the first direction X; where, the gate line groups 2 may be located at a gap between adjacent rows of pixel electrodes 40; and specifically, the two line gates 20 of the gate group 2 may be a first gate line 21 and a second gate line 22 respectively;
a plurality of data lines 3 extending in a second direction Y, where the second direction Y intersecting with the first direction X; optionally, the second direction Y is perpendicular to the first direction Y; and specifically, the first direction X may be a direction of a pixel electrode row, and the second direction Y may be a direction of a pixel electrode column;
a plurality of transistors T, where the transistor includes: a first electrode TA electrically connected with the data line 3, and a second electrode TB; where a part of an orthographic projection of the second electrode TB of the transistor on the substrate 1 is located between orthographic projections of two gate lines 20 of a same gate group 2 on the substrate 1; and specifically, the first electrode TA of the transistor may be a source, and the second electrode TB of the transistor may be a drain;

a plurality of pixel electrode groups 4, where an orthographic projection of at least a part of the pixel electrode group 4 on the substrate 1 is located in a region formed due to intersection of the gate line groups 2 and the data lines 3; the pixel electrode group 4 includes: two pixel electrodes 40 arranged in the first direction X. Specifically, the two pixel electrodes 40 of a same pixel electrode group 4 may be a first pixel electrode 41 and a second pixel electrode 42 respectively. Specifically, the second pixel electrode 42 may be located at a side of the first pixel electrode 41 away from the data line 3 electrically connected; and specifically, the two pixel electrodes 40 of the same pixel electrode group 4 may be electrically connected with a same data line 3 through different transistors T; and
a plurality of first common lines 51, where an orthographic projection of the first common line 51 on the substrate 1 is located between the orthographic projections of the two gate lines 20 of the same gate group 2 on the substrate 1, and at least part of the orthographic projection of the first common line 51 on the substrate 1 overlaps with at least part of the orthographic projection of the second electrode TB of the transistor on the substrate 1.

In the embodiments of the disclosure, the part of the orthographic projection of the second electrode TB of the transistor on the substrate 1 is located between the orthographic projections of the two gate lines 20 of the same gate group 2 on the substrate 1, the orthographic projection of the first common line 51 on the substrate 1 is located between the orthographic projections of the two gate lines 20 of the same gate group 2 on the substrate 1, and at least part of the orthographic projection of the first common line 51 on the substrate 1 overlaps with at least part of the orthographic projection of the second electrode TB of the transistor on the substrate 1. Therefore, in a weakening process, the second electrode TB of the transistor and the first common line 51 may be connected, and a connecting via may be located between the orthographic projections of the two gate lines 20 on the substrate 1. Since a light-blocking layer (such as a black matrix) is usually arranged corresponding to the two gate lines 20 and a region between the two gate lines 20, it is possible to hide the weakening via in a region where the light-blocking layer is located, thereby solving the problems of transmittance loss caused by low pixel aperture ratio in the Dual Gate structure and contrast reduction caused by metallic reflection in an opening region. Moreover, compared to a conventional array substrate with common lines respectively arranged on both sides of the gate line group 2, the embodiments of the disclosure can further reduce one common line, reduce the width of the light-blocking layer (such as the black matrix), and have a more significant effect on increasing the aperture ratio. In addition, compared to the conventional array substrate where there is usually a problem of quality and yield affected by abnormal display due to non-stick alignment liquid at the via, in the embodiments of the disclosure, a first via K1 is located in the region where the light-blocking layer (such as the black matrix) is located, and an abnormal display region is effectively blocked by the light-blocking layer (such as the black matrix), which can increase a margin width of an alignment liquid coating process and reduce process difficulty.

In some embodiments, as shown in FIG. 1A and FIG. 1E, the pixel electrode 40 include a pixel electrode body PA and a pixel electrode lapping portion PB extending from one end of the pixel electrode body PA. A part of an orthographic projection of the pixel electrode lapping portion PB on the substrate 1 is located between the orthographic projections of the two gate lines 20 of the same gate group 2 on the substrate 1, and the part of the orthographic projection of the pixel electrode lapping portion PB on the substrate 1 overlaps with the at least part of the orthographic projection of the second electrode TB of the transistor on the substrate 1. In the embodiments of the disclosure, the part of the orthographic projection of the pixel electrode lapping portion PB on the substrate 1 overlaps with the at least part of the orthographic projection of the second electrode TB of the transistor on the substrate 1, so that the pixel electrode lapping portion PB and the second electrode TB of the transistor are electrically connected at the overlapping position through a via, thereby achieving an electrical connection between the pixel electrode 40 and the transistor T.

In some embodiments, as shown in FIG. 1A and FIG. 1E, a shape of the orthographic projection of the pixel electrode body PA on the substrate 1 may be rectangular. A; length of the orthographic projection of the pixel electrode body PA on the substrate 1 in the second direction Y may be greater than a length thereof in the first direction X. In some embodiments, as shown in FIG. 1A and FIG. 1E, the pixel electrode lapping portion PB extending from one end of the pixel electrode body PA may be a pixel electrode lapping portion PB extending from one corner of the rectangular pixel electrode body PA.

In some embodiments, as shown in FIG. 1A and FIG. 1E, the orthographic projection of at least part of the pixel electrode group 4 on the substrate 1 being located in the region formed due to the intersection of the gate line groups 2 and the data lines 3, may be that the orthographic projection of the pixel electrode body PA of the pixel electrode group 4 on the substrate 1 is located in the region formed due to the intersection of the gate line groups 2 and the data lines 3.

In some embodiments, as shown in FIG. 1A and FIG. 1E, the pixel electrode lapping portion PB includes: first sub-lapping portion PB1 extending in the second direction Y and a second sub-lapping portion PB2 extending in the first direction X. One end of the first sub-lapping portion PB1 is electrically connected with the pixel electrode body PA, and the other end is electrically connected with the second sub-lapping portion PB2. An orthographic projection of the second sub-lapping portion PB2 on the substrate 1 is located between the orthographic projections of the two gate lines 20 of the same gate group 2 on the substrate 1. In this way, the electrical connection between the pixel electrode 40 and the transistor T may be achieved through the electrical connection between the second sub-lapping portion PB2 and the second electrode TB of the transistor at the overlapping position through a via.

In some embodiments, as shown in FIG. 1A and FIG. 1E, the part of the orthographic projection of the pixel electrode lapping portion PB on the substrate 1 overlapping with the at least part of the orthographic projection of the second electrode TB of the transistor on the substrate 1, may be that the orthographic projection of the second sub-lapping portion PB2 on the substrate 1 overlaps with the orthographic projection of the second electrode TB of the transistor on the substrate 1.

In some embodiments, as shown in FIG. 1A and FIG. 1E, the part of the orthographic projection of the pixel electrode lapping portion PB on the substrate 1 being located between the orthographic projections of the two gate lines 20 of the same gate group 2 on the substrate 1, may be that the orthographic projection of the second sub-lapping portion PB2 on the substrate 1 is located between the orthographic projections of the two gate lines 20 of the same gate group 2 on the substrate 1.

In some embodiments, as shown in FIG. 1A and FIG. 1E, a shape of the orthographic projection of the first sub-lapping portion PB1 on the substrate 1 may be a stripe.

In some embodiments, as shown in FIG. 1A and FIG. 1E, the second sub-lapping portion PB2 may further include: a third sub-lapping portion PB3 and a fourth sub-lapping portions PB4 arranged sequentially in the first direction X. One end of the third sub-lapping portion PB3 is electrically connected with the first sub-lapping portion PB1, and the other end is electrically connected with the fourth sub-lapping portion PB4. A maximum length d2 of the fourth sub-lapping portion PB4 in the second direction Y is greater than a maximum length d1 of the third sub-lapping portion PB3 in the second direction Y. In this way, the pixel electrode 40 is electrically connected with the second electrode TB of the transistor at the fourth sub-lapping portion PB4.

In some embodiments, as shown in FIG. 1A and FIG. 1E, the two pixel electrodes 40 of the same pixel electrode group 4 are electrically connected with the same data line 3 through the transistor T; and in the same pixel electrode group 4, the second sub-lapping portions PB2 of the two pixel electrodes 40 extend from the first sub-lapping portions PB1 towards a side of the data line 3 electrically connected. Specifically, as shown in FIG. 1E, in a first one of pixel electrode row from top to bottom, a second one of pixel electrodes 40 from the left and a third one of pixel electrodes 40 from the left are both electrically connected with the same data line 3 at the right side of the two pixel electrodes, the second sub-lapping portion PB2 of the second one of pixel electrodes 40 from the left extends from the first sub-lapping portion PB1 towards the side of the data line 3 electrically connected at the right side, and the second sub-lapping portion PB2 of the third one of pixel electrodes 40 from the left also extends from the first sub-lapping portion PB1 towards the side of the data line 3 electrically connected at the right side. In this way, while allowing the array substrate to have the weakening via hidden in the position blocked by the light-blocking layer, the plurality of second overlap portions PB of the entire array substrate can be distributed in a regular and orderly manner, thereby achieving a beautiful layout and saving space.

In some embodiments, as shown in FIG. 1A and FIG. 1E, two second sub-lapping portions PB2 of two pixel electrodes 40 adjacent in the second direction Y extend in opposite directions from the first sub-lapping portions PB1. Specifically, as shown in FIG. 1E, in a first one of pixel electrode rows, the second sub-lapping portion PB2 of the third one of pixel electrodes 40 from the left extends to the right side from the first sub-lapping portion PB1; and in a second one of pixel electrode rows, the second sub-lapping portion PB2 of the third one of pixel electrodes 40 from the left extends to the left side from the first sub-lapping portion PB1. In this way, while allowing the array substrate to have the weakening via hidden in the position blocked by the light-blocking layer, the plurality of second overlap portions PB of the entire array substrate can be distributed in a regular and orderly manner, thereby achieving a beautiful layout and saving space.

In some embodiments, as shown in FIG. 1A and FIG. 1E, the array substrate includes: a first axis e1 between the adjacent pixel electrodes 40 and extending in the second direction Y; and in the first direction X, at least two of adjacent second sub-lapping portions PB2 have at least parts symmetrical to each other with respect to the first axis e1. In this way, while allowing the array substrate to have the weakening via in the position blocked by the light-blocking layer, the plurality of second overlap portions PB of the entire array substrate can be distributed in a regular and orderly manner, thereby achieving a beautiful layout and saving space.

Dual gate design presents significant challenges to panel design and process, mainly including: 1, a decrease in the quantity of data line and an increase in the quantity of the gate line make charging the panel more difficultly; 2, decreases of pixel area and pixel storage capacitance Ccs, and an almost unchanged parasitic capacitance of the pixel, lead to susceptibility to the parasitic capacitance (such as a coupling capacitance Cgs (a capacitance between the Gate and the Pixel, where the Pixel may be considered as an overall structure formed by the pixel electrode and other structures electrically connected with the pixel electrode), and result in poor shaking pattern. For a VA product, its storage capacitance is further decreased compared to an ADS product, which makes a VA Dual gate product more susceptible to the parasitic capacitance, resulting in various defects such as the shaking pattern.

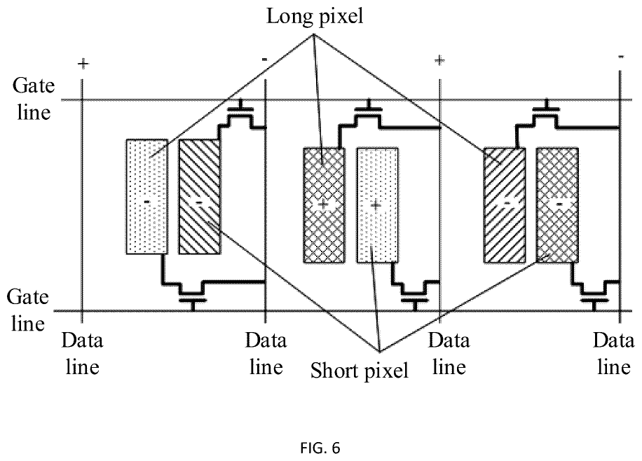

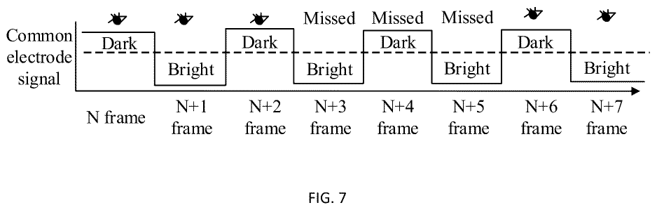

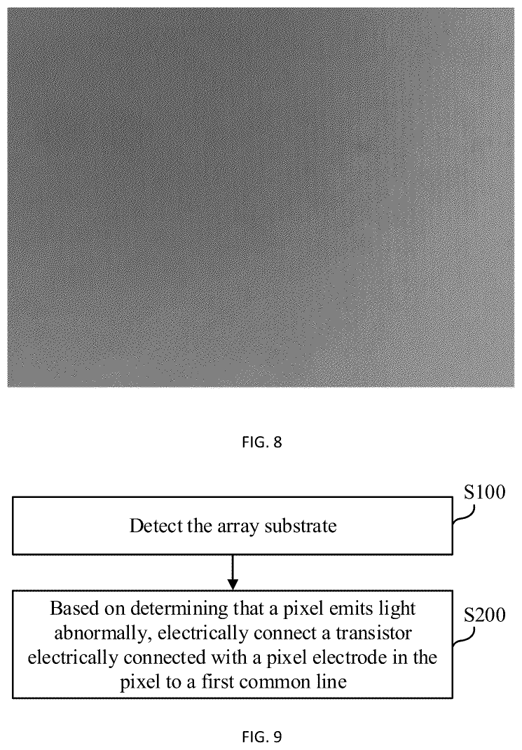

Specifically, in the Dual gate design, as shown in FIG. 6, a signal loaded on a long pixel and a signal loaded on a data line adjacent to the long pixel (as shown in FIG. 6, the first one of long pixels from left to right and the leftmost data line) are opposite in polarity, and when the coupling of data line signal (Data) with a common electrode signal (COM) fluctuates, it will cause the long pixel to become brighter. A signal loaded on a short pixel and a signal loaded on a data line adjacent to the short pixel (as shown in FIG. 6, the first one of short pixels from left to right and the second one of data lines from left to right) are the same in polarity, and when the coupling of the data line signal (Data) with the common electrode signal (COM) fluctuates, it will cause the short pixel to become darker. Half of the signals corresponding to color pixels in space are of the same polarity, averaging based on effect cannot be performed, and averaging based on time is necessary. However, in terms of time, when a head moves, several frames of images may be lost, further causing a decrease in the average effect in space, as shown in FIG. 7. When the head sways left and right, scrolling vertical patterns can be seen on a screen, which is indicated as the shaking pattern, as shown in FIG. 8.

In view of this, in some embodiments, as shown in FIG. 1A and FIG. 1D, the plurality of transistors T include: first transistors T1 and second transistors T2. In the same pixel electrode group 4, one of the pixel electrodes 40 is electrically connected with the data line 3 through the first transistor T1, and the other one of the pixel electrodes 40 is electrically connected with the data line 3 through the second transistor T2. The array substrate includes: a second axis e2 passing through a center of the pixel electrode 40 and extending in the first direction X, and among the first transistor T1 and the second transistor T2 which are electrically connected with the same pixel electrode group 4, a second electrode TB of the first transistor T1 and the second electrode TB of the second transistor T2 are symmetrical with respect to the second axis e2. Specifically, for example, as shown in FIG. 1A and FIG. 1D, a first transistor T1 indicated by a dashed circle and a second transistor T2 indicated by another dashed circle are the first transistor T1 and the second transistor T2 which are electrically connected with the same pixel electrode group 4, and the second electrode TB of the first transistor T1 indicated by the dashed circle and the second electrode TB of the second transistor T2 indicated by another dashed circle are symmetrical with respect to the second axis e2.

In the embodiments of the disclosure, among the first transistor T1 and the second transistor T2 which are electrically connected with the same pixel electrode group 4, the second electrode TB of the first transistor T1 and the second electrode TB of the second transistor T2 are symmetrical with respect to the second axis e2, and can adapt to distribution positions of the second sub-lapping portion PB2 of the first pixel electrode 41 and the second sub-lapping portion PB2 of the second pixel electrode 42, achieving the electrical connection between the second electrode TB of the transistor and the pixel electrodes 40, allowing the plurality of second electrodes TB of the transistors on the entire array substrate be distributed in a regular and orderly manner, thereby achieving a beautiful layout and saving space. Moreover, in the embodiments of the disclosure, among the first transistor T1 and the second transistor T2 which are electrically connected with the same pixel electrode group 4, the second electrode TB of the first transistor T1 and the second electrode TB of the second transistor T2 are symmetrical with respect to the second axis e2, so that a first capacitance C1 is substantially equal to a second capacitance C2. Here, the first capacitance C1 is a capacitance formed by the gate line 20 and a first pixel structure, and the second capacitance C2 is a capacitance formed by the gate line 20 and a second pixel structure (the first pixel structure may include: the first pixel electrode 41, and the second electrode TB of the transistor connected with the first pixel electrode 41; and the second pixel structure may include: the second pixel electrode 42, and the second electrode TB of the transistor connected with the second pixel electrode 42), thereby relieving a problem of shaking pattern defect in a dual-gate structure display panel in the related art.

It should be noted that in an actual manufacturing process, it may be difficult to make the first capacitance C1 and the second capacitance C2 completely equal. Therefore, in the embodiments of the disclosure, a difference between the first capacitance C1 and the second capacitance C2 may range from 0 F to 0.0001 F, which means that the two are considered to be substantially equal. Specifically, for example, the difference between the two ranges from 0 F to 0.00007 F ; specifically, for example, the difference between the two is 0; specifically, for example, the difference between the two is 0.00007 F; specifically, for example, the difference between the two is 0.000061 F; and specifically, the difference between the two is 0.000036 F. Specifically, the first capacitance C1 and the second capacitance C2 in the embodiments of the disclosure may be obtained through software simulation before manufacturing the array substrate.

Specifically, the transistor may further include an active pattern 8, and the first pixel structure may further include: an active pattern 8 of the transistor T connected with the first pixel electrode 41; and the second pixel structure may further include an active pattern 8 of the transistor T connected with the second pixel electrode 42. Specifically, the capacitance generated by the gate line 20 and the active pattern 8 may only be present during the period when the transistor is turned on, and it may be considered that there is no capacitance formed by the gate line 20 and the active pattern 8 during the period when the transistor is turned off, which does not affect the first capacitance C1 or the second capacitance C2. When the transistor works in an on state, the active pattern 8 of the transistor is electrically connected with the second electrode TB of the transistor, and the second electrode TB is electrically connected with the first pixel electrode 41. At this time, the first capacitance C1 may include a capacitance formed between the gate line 20 and the first pixel electrode 41, a capacitance formed between the gate line 20 and the second electrode TB of the transistor, and a capacitance formed between the gate line 20 and the active pattern 8. When the transistor T works in the on state, the active pattern 8 of the transistor T is electrically connected with the second electrode TB of the transistor, and the second electrode TB of the transistor is electrically connected with the second pixel electrode 42. At this time, the second capacitance C2 may include a capacitance formed between the gate line 20 and the second pixel electrode 42, a capacitance formed between the gate line 20 and the second electrode TB of the transistor, and a capacitance formed between the gate line 20 and the active pattern 8.

In some embodiments, as shown in FIG. 1A and FIG. 1D, in the same pixel electrode group 4, one of the pixel electrodes 40 being electrically connected with the data line 3 through the first transistor T1, and the other one of the pixel electrodes 40 being electrically connected with the data line 3 through the second transistor T2, may be that the first pixel electrode 41 in the same pixel electrode group 4 is electrically connected with the data line 3 through the first transistor T1, and the second pixel electrode 42 in the same pixel electrode group 4 is electrically connected with the data line 3 through the second transistor T2.

In some embodiments, as shown in FIG. 1A and FIG. 1D, among the first transistor T1 and the second transistor T2 which are electrically connected with the same pixel electrode group 4, the second electrode TB of the first transistor T1 and the second electrode TB of the second transistor T2 are both located between the first axis e1 and the data line 3 electrically connected. Specifically, for example, as shown in FIG. 1A and FIG. 1D, the first transistor T1 indicated by the dashed circle and the second transistor T2 indicated by another dashed circle are the first transistor T1 and the second transistor T2 which are electrically connected with the same pixel electrode group 4, and the second electrode TB of the first transistor T1 indicated by the dashed circle and the second electrode TB of the second transistor T2 indicated by another dashed circle are both located between the first axis e1 and the data line 3 electrically connected. In this way, distribution positions of the second sub-lapping portion PB2 of the first pixel electrode 41 and the second sub-lapping portion PB2 of the second pixel electrode 42 are adapted, the electrical connection between the second electrode TB of the transistor and the pixel electrode 40 is achieved, and the plurality of second electrodes TB of the transistors on the entire array substrate may be made to be arranged in a regular and orderly manner, thereby achieving a beautiful layout and saving space, which is conducive to relieving the problem of shaking pattern defect in the dual-gate structure display panel in the related art.

In some embodiments, as shown in FIG. 1A and FIG. 1D, second electrodes TB2 of at least two transistors adjacent in the second direction Y are symmetrical with respect to the second axis e2. Specifically, for example, in FIG. 1D, a second electrode TB of a first one of transistors in a direction from top to bottom at a left side of the right data line 3 and a second electrode TB of a second one of transistors in the direction from top to bottom are symmetrical with respect to the second axis e2. For another example, a second electrode TB of a first one of transistors in the direction from top to bottom at a right side of the left data line 3 and a second electrode TB of a second one of transistors in the direction from top to bottom are symmetrical with respect to the second axis e2.

In some embodiments, as shown in FIG. 1A and FIG. 1D, the second electrode TB of the transistor include: a first portion TB1 extending in the second direction Y, and a second portion TB2 connected with the first portion TB1 and extending in the first direction X. The first portions TB1 of the second electrodes of at least two adjacent transistors in the second direction Y extend from the second pole second portions TB2 towards a side of the pixel electrode body PA electrically connected. Specifically, for example, as shown in FIG. 1A and FIG. 1D, a second electrode TB of a first one of transistors in the direction from top to bottom at the left side of the right data line 3 and a second electrode TB of a second one of transistors in the direction from top to bottom are both electrically connected to the pixel electrode group 4 (the pixel electrode group 4 includes a second one of pixel electrodes 40 and a third one of pixel electrodes 40 in a direction from left to right) in the first one of pixel electrode rows in the direction from top to bottom, and then the first one of first portions TB1 in the direction from top to bottom at the left side of the right data line 3, and the second one of first portions TB1 in the direction from top to bottom both extend from the corresponding second portions TB2 towards the side of the pixel electrode body PA electrically connected.

In some embodiments, as shown in FIG. 1A and FIG. 1D, for two second electrodes TB of transistors which are at least partially adjacent in the first direction X, first portions TB1 of the two electrodes extend in opposite directions from second portions TB2 of the two electrodes. For example, as shown in FIG. 1D, one of the two adjacent first portions TB1 in the second row extends downwards from the corresponding second portion TB2, and the other extends upwards from the corresponding second portion TB2. In this way, the two diagonal pixel electrodes 40 are electrically connected with the different data lines 3 respectively, and the plurality of second electrodes TB of the transistors on the entire array substrate may be made to be arranged in a regular and orderly manner, thereby achieving a beautiful layout and saving space.

In some embodiments, as shown FIG. 1A and FIG. 1D,, two second portions TB2 of two transistors T which are at least partially adjacent in the first direction X are symmetrical with respect to the first axis e1. Specifically, for example, in FIG. 1D, the second one of second portions TB2 in the second row and a third one of second portions TB2 are symmetrical with respect to the first axis e1. In this way, while making the array substrate to have the weakening via hidden in the position blocked by the light-blocking layer, the plurality of second electrodes TB of the transistors on the entire array substrate can be distributed in the regular and orderly manner, thereby achieving a beautiful layout and saving space.

In some embodiments, as shown in FIG. 1A, FIG. 1C, FIG. 1D and FIG. 1I, the transistor further include: an active pattern 8. The active pattern 8 include: a first active outer edge f1 extending in the second direction Y, and a second active outer edge f2. In a same transistor T, an orthographic projection of the second active outer edge f2 on the substrate 1 is located at a side of the first active outer edge f1 away from the data line 3 connected with the transistor T. The first electrode TA of the transistor includes: a first portion TA1 extending in the second direction Y, and a second portion TA2 for connecting the first portion and the data line 3. At least a part of the orthographic projection of the first active outer edge f1 on the substrate 1 coincides with at least a part of an orthographic projection of an outer edge of the first portion TA1 of the first electrode at a side of the first portion TA1 away from the first portion TB1 of the second electrode on the substrate. At least a part of the orthographic projection of the second active outer edge f2 on the substrate 1 coincides with at least a part of an orthographic projection of an outer fringe of the first portion TB1 of the second electrode at a side of the first portion TB1 away from the first portion TA1 of the first electrode on the substrate 1. Specifically, for example, in FIG. 1I, at least a part of the orthographic projection of the first active outer edge f1 on the substrate 1 coincides with at least a part of the orthographic projections of the right edge of the first portion TA1 of the first electrode on the substrate; and at least a part of the orthographic projection of the second active outer edge f2 on the substrate 1 coincides with at least a part of the orthographic projection of the left edge of the first portion TB1 of the second electrode on the substrate 1. In this way, line widths of the first portion TA1 of the first electrode and the first portion TB1 of the second electrode may be minimized, thereby reducing a parasitic capacitance between the layer where the data lines 3 are located and the layer where the gate lines 20 are located, and achieving a high refresh and charging ratio.

In some embodiments, as shown in FIG. 1A and FIG. 1H, the array substrate further includes: a first insulating layer F1 between a layer where the pixel electrode groups 4 are located and a layer where the second electrodes TB2 of the transistors are located. The first insulating layer F1 includes first vias K1, and the pixel electrode lapping portions PB are electrically connected with the second electrodes TB of the transistor through the first vias K1.

In some embodiments, as shown in FIG. 1A, FIG. 1H, and FIG. 1J, FIG. 1J may be a schematic diagram of FIG. 1I after weakening treatment. When there is a light emission defect in a pixel, the second electrode TB of the transistor and a first common line 51 directly below it may be connected to make the pixel at a common (Vcom) potential and displayed as a dark spot.

In some embodiments, as shown in FIG. 1A, FIG. 1H, and FIG. 1J, at least a part of an orthographic projection of the weakening via K2 on the substrate 1 may overlap with at least a part of an orthographic projections of the first via K1 on the substrate 1. In some embodiments, all of the orthographic projection of the weakening via K2 on the substrate 1 may overlap with all of the orthographic projection of the first via K1 on the substrate 1.

In some embodiments, as shown in FIG. 1A and FIG. 1H, an orthographic projection of the first common line 51 on the substrate 1 overlap with at least a part of the orthographic projection of the first via K1 on the substrate 1. In some embodiments, the orthographic projection of the first common line 51 on the substrate 1 may cover the orthographic projection of the first via K1 on the substrate 1.

In some embodiments, as shown in FIG. 1A, FIG. 1F, FIG. 1G and FIG. 1H, the array substrate further includes: a color resistor layer 6 at a side of a layer where the pixel electrodes 40 are located facing the substrate 1; and the first insulating layer F1 includes the color resistor layer 6. In the embodiment of the disclosure, the array substrate further includes the color resistor layer 6. On the one hand, because the color resistor layer is relatively thick, a distance between the data lines 3 and the layer where the pixel electrodes 40 are located may be increased, and the parasitic capacitance between the data lines 3 and the pixel electrodes 40 may be reduced. On the other hand, for a curved product, when the color resistor layer 6 is arranged on the array substrate, during bending, the pixel electrodes 40 and the color resistor layer 6 move simultaneously, which can avoid a problem of color mixing.

In some embodiments, as shown in FIG. 1A, FIG. 1F, FIG. 1G and FIG. 1H, the layer where the data lines 3 are located may be located at a side of a layer where the gate lines 20 are located facing away from substrate 1, the layer where the pixel electrodes 40 are located may be located at a side of the layer where the data lines 3 are located facing away from the layer where the gate lines 20 are located, and the active pattern 8 may be located between the layer where the data lines 3 are located and the layer where the gate lines 20 are located (not shown in FIG. 1A, FIG. 1F, FIG. 1G and FIG. 1H). A gate insulating layer 11 may further be arranged between the layer where the gate lines 20 are located and the layer where the active pattern 8 is located, a passivation layer 12 may further be arranged between the layer where the data lines 3 are located and the layer where the pixel electrodes 4 are located, and a planarization layer 13 may further be arranged between the passivation layer 12 and the layer where the pixel electrodes 40 are located.

In some embodiments, as shown in FIG. 1A, FIG. 1F, FIG. 1G and FIG. 1H, the first insulating layer F1 may further include the passivation layer 12 located on a side of the color resistor layer 6 facing the substrate 1, and the planarization layer 13 located on a side of the color resistor layer facing away from the substrate 1.

In some embodiments, the planarization layer 13 may be an organic film layer. In some embodiments, the passivation layer 12 may be a PVX layer, for example, including a silicon nitride material layer.

In some embodiments, as shown in FIG. 1A, FIG. 1H and FIG. 1K, the first via K1 may be designed as a sleeve via. The first via K1 may include a planarization layer via K11 in the planarization layer 13, a color resistor layer via K12 in the color resistor layer 6, and a passivation layer via K13 in the passivation layer 12. An orthographic projection of the planarization layer via K11 on the substrate 1 coincides with an orthographic projection of the passivation layer via K13 on the substrate 1. An orthographic projection of the color resistor layer via K12 on the substrate 1 may cover the orthographic projection of the planarization layer via K11 on the substrate 1. An area of the orthographic projection of the color resistor layer via K12 on the substrate 1 may be greater than an area of the orthographic projection of the planarization layer via K11 on the substrate 1.

In some embodiments, as shown in FIG. 1A, FIG. 1H, FIG. 1J and FIG. 1K, an orthographic projection of a black matrix 91 on the substrate 1 may cover the orthographic projections of the first via K1 on the substrate 1, and the orthographic projection of the black matrix 91 on the substrate 1 may cover the orthographic projection of the weakening via K2 on the substrate 1. In this way, the first via K1 for connecting the pixel electrode 40 and the transistor T, and the weakening via K2 both are arranged in a region covered by the black matrix 91, which can avoid separately arranging the light-blocking layers for the first via K1 and the weakening via K2, thereby increasing the aperture ratio of the display panel.

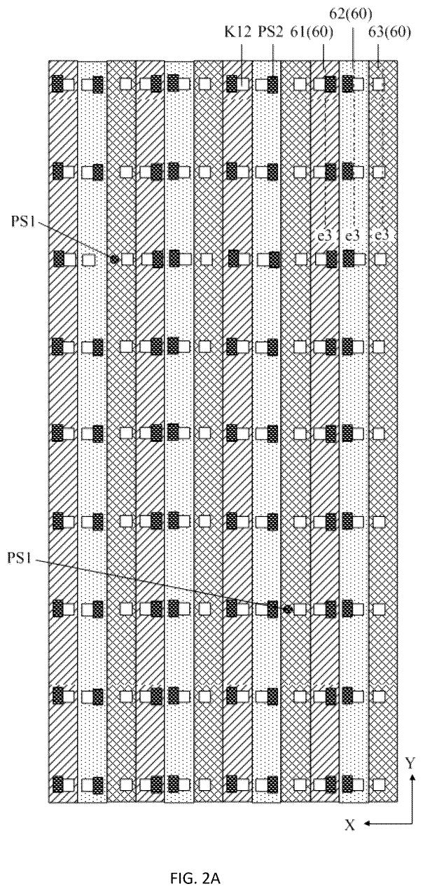

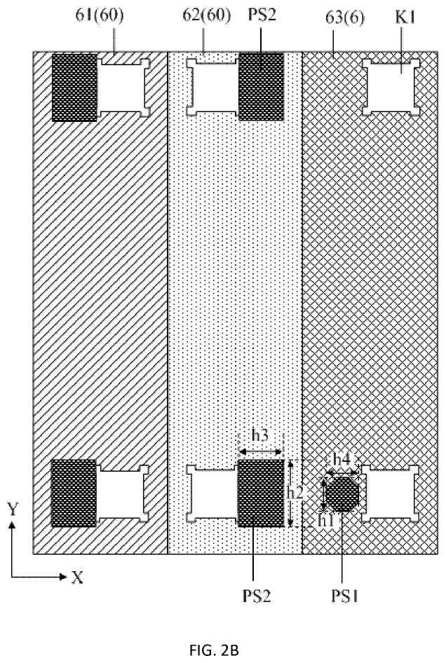

In some embodiments, as shown in FIG. 1A, FIG. 1F, FIG. 1G, FIG. 1H, FIG. 1K, FIG. 2A and FIG. 2B, the color resistor layer 6 may include: a plurality of color resistor bars 60 extending in the second direction. The plurality of color resistor bars 60 may include: first color resistors 61, second color resistors 62, and third color resistors 63. The first color resistor 61 may extend in the second direction Y, and an orthographic projection of the first color resistor on the substrate 1 may cover orthographic projections of a column of pixel electrodes 40 on the substrate 1. The second color resistor 62 may extend in the second direction Y, and an orthographic projection of the second color resistor on the substrate 1 may cover the orthographic projections of the column of pixel electrodes 40 on the substrate 1. The third color resistor 63 may extend in the second direction Y, and an orthographic projection of the third color resistor on the substrate 1 may cover orthographic projections of the column of pixel electrodes 40 on the substrate 1. The first color resistor 61, the second color resistor 62, and the third color resistor 63 may be arranged alternately in the first direction X.

In some embodiments, the first color resistor 61 may be a red color resistor, the second color resistor 62 may be a green color resistor, and the third color resistor 63 may be a blue color resistor.

In some embodiments, as shown in FIG. 1A, FIG. 1F, and FIG. 1G, a color resistor overlap portion 64 may be arranged between the adjacent first color resistor 61 and the second color resistor 62, a color resistor overlap portion 64 may be arranged between the adjacent second color resistor 62 and the third color resistor 63, and a color resistor overlap portion 64 may be arranged between the adjacent third color resistor 63 and the first color resistor 61. In some embodiments, as shown in FIG. 1A, FIG. 1F, and FIG. 1G, at least part of the orthographic projection of the color resistor overlap portion 64 on the substrate 1 may coincide with at least part of the orthographic projection of the data line 3 on the substrate 1.

In some embodiments, as shown in FIG. 2A and FIG. 2B, the array substrate further includes: a plurality of first spacers PS1 and a plurality of second spacers PS2. A length of the first spacer PS1 in a direction perpendicular to the substrate 1 is greater than a length of the second spacer PS2 in a direction perpendicular to the substrate 1, that is, the first spacer PS1 may be higher than the second spacers PS2. A shape of an orthographic projection of the first spacer PS1 on the substrate 1 is different from a shape of an orthographic projection of the second spacer PS2 on the substrate 1. In the embodiments of the disclosure, the array substrate further includes the plurality of first spacers PS1 and the plurality of second spacers PS2, and the shapes of the orthographic projections of the first spacers PS1 on the substrate 1 are different from the shapes of the orthographic projections of the second spacers PS2 on the substrate 1. That is, the first spacers PS1 and the second spacers PS2 are located on the array substrate, and are vertical to the counter substrate. A flatness of the counter substrate is higher than that of the array substrate, so that crushed pixels generated during tapping can be avoided. An area of a rectangular orthographic projection of the second spacer PS2 is the largest, and a contact area increases when pressed, resulting in better supporting effect.

In some embodiments, the first spacers PS1 may be main spacers; and the second spacers PS2 may be auxiliary spacers. In some embodiments, as shown in FIG. 2A and FIG. 2B, a distribution density of the first spacers PS1 may be smaller than a distribution density of the second spacers PS2. That is, in a region with the same area, the quantity of the first spaces PS1 may be smaller than the quantity of the second spacers PS2.

In some embodiments, as shown in FIG. 2B, a maximum length h2 of the second spacer PS2 in the second direction Y is greater than a maximum length h1 of the first spacer PS1 in the second direction Y. In some embodiments, as shown in FIG. 2A and FIG. 2B, a maximum length h3 of the second spacer PS2 in the first direction X is greater than a maximum length h4 of the first spacer PS1 in the first direction X. In some embodiments, as shown in FIG. 2A and FIG. 2B, an area of the orthographic projection of the second spacer PS2 on the substrate 1 is greater than an area of the orthographic projection of the first spacer PS1 on the substrate 1.

In some embodiments, the length h4 of the orthographic projection of the first spacer PS1 on the substrate 1 in the first direction X may be equal to the length h1 of the orthographic projection of the first spacer PS1 on the substrate 1 in the second direction Y; and the length h3 of the orthographic projection of the second spacer PS2 on the substrate 1 in the first direction X may be smaller than the length h2 of the orthographic projection of the second spacer PS2 on the substrate 1 in the second direction Y.

In some embodiments, as shown in FIG. 2A and FIG. 2B, the orthographic projection of the first spacer PS1 on the substrate 1 may be octagonal; and the orthographic projection of the second spacer PS2 on substrate 1 may be rectangular. In some embodiments, the orthographic projection of the first spacer PS1 on the substrate 1 may further be pentagonal, hexagonal, or decagonal.

In some embodiments, as shown in FIG. 2A and FIG. 2B, the second spacers PS2 may be located in regions where the first color resistor 61 and the second color resistor 62 are located, and the first spacers PS1 may be located in a region where the third color resistor 63 is located.

In some embodiments, as shown in FIG. 2A, taking 4 columns*8 rows of pixels (each pixel includes three sub pixels of a red sub pixel, a green sub pixel, and a blue sub pixel) as a unit, each unit is provided with two first spacers PS1, where one of the first spacers PS1 (as shown in FIG. 2A, the first spacer PS1 on the left side) is used as an inspection spacer (which may be used to specifically identify the pixel position, for example, when the first spacer PS1 is found, it may be determined that the position on the left side of the first spacer PS1 is a position of the green sub pixel). In order to facilitate production line inspection, the green sub pixel next to the first spacer PS1 may not be provided with the second spacer PS2.

In some embodiments, as shown in FIG. 2A, in the 4 columns*8 rows of pixels (each pixel including the three sub pixels of the red sub pixel, the green sub pixel, and the blue sub pixel), one second spacer PS2 may be provided at a position corresponding to each red sub pixel in a column of first color resistor 61, and one second spacer PS2 may be configured at a position corresponding to each green sub pixel in a column of second color resistor 62; and only one first spacer PS1 may be configured at a position corresponding to one of the blue sub pixels in a column of third color resistor 63.

In some embodiments, at least part of the orthographic projection of the first spacer PS1 on the substrate 1 may not overlap with at least a part of the orthographic projection of the transistor T on the substrate 1, and at least part of the orthographic projection of the second spacer PS2 on the substrate 1 may not overlap with at least part of the orthographic projection of the transistor T on the substrate 1. In this way, the possibility of affecting the performance of the transistor T when the first spacer PS1 and the second spacer PS2 are arranged in the region where the transistor T is located may be avoided.

In some embodiments, as shown in FIG. 2A and FIG. 2B, the color resistor bar 60 may include a third axis e3 extending in the second direction Y. Among at least part of adjacent color resistor bars 60, centers of the orthographic projections of the second spacers PS2 on the substrate 1 are located at different sides of the third axis e3. For example, in FIG. 2A, in the second on of color resistor bars 60 from the right, the centers of the orthographic projections of the second spacers PS2 on the substrate 1 are located at the left side of the third axis e3, while in the third one of color resistor bars 60 from the right, the centers of the orthographic projections of the second spacers PS2 on the substrate 1 are located on the right side of the third axis e3. In this way, the positions of the transistors T are adapted, and the possibility of affecting the performance of the transistors T when the first spacers PS1 and the second spacers PS2 are arranged in the regions where the transistors T are located may be avoided.

In some embodiments, as shown in FIG. 2A and FIG. 2B, the color resistor bar 60 may include the third axis e3 extending in the second direction Y. Among at least part of adjacent color resistor bars 60, centers of orthographic projections of color resistor layer vias K12 on the substrate 1 are located at different sides of the third axis e3. For example, in FIG. 2A, in the second one of color resistor bars 60 from the right, the centers of the orthographic projections of the color resistor layer vias K12 on the substrate 1 are located on the right side of the third axis e3, while in the third one of color resistor bars 60 from the right, the centers of the orthographic projections of the color resistor layer vias K12 on the substrate 1 are located on the left side of the third axis e3.

In some embodiments, as shown in FIG. 2A and FIG. 2B, a part of an outer edge of the orthographic projection of the second spacer PS2 on the substrate 1 coincides with a part of an outer edge of the orthographic projection of the color resistor layer via K12 on the substrate 1.

In some embodiments, at least part of the orthographic projection of the first spacer PS1 on the substrate 1 overlaps with at least part of the orthographic projection of the first common line 51 on the substrate 1; and at least part of the orthographic projection of the second spacer PS2 on the substrate 1 overlaps with at least part of the orthographic projection of the first common line 51 on the substrate 1.

In some embodiments, at least part of the orthographic projection of the black matrix 91 on the substrate 1 overlaps with at least part of the orthographic projection of the first spacer PS1 on the substrate 1, and at least part of the orthographic projection of the black matrix 91 on the substrate 1 overlaps with at least part of the orthographic projection of the second spacer PS2 on the substrate 1. In some embodiments, the orthographic projection of the black matrix 91 on the substrate 1 covers the orthographic projection of the first spacer PS1 on the substrate 1, and the orthographic projection of the black matrix 91 on the substrate 1 covers the orthographic projection of the second spacer PS2 on the substrate 1.

In some embodiments, at least part of the orthographic projection of the first spacer PS1 on the substrate 1 overlaps with at least part of an orthographic projection of a gap between adjacent pixel electrode rows on the substrate 1; and at least part of the orthographic projection of the second spacer PS2 on the substrate 1 overlaps with at a part of the orthographic projection of the gap between the adjacent pixel electrode rows on the substrate 1. In some embodiments, the orthographic projection of the gap between the adjacent pixel electrode rows covers the orthographic projection of the first spacer PS1 on the substrate 1; and the orthographic projection of the gap between the adjacent pixel electrode rows on the substrate 1 covers the orthographic projection of the second spacer PS2 on the substrate 1.

In some embodiments, as shown in FIG. 1A and FIG. 1B, the first common line 51 include: a first sub common line portion 511 and a second sub common line portion 512 arranged in the first direction X. At least part of an orthographic projection of the first sub common line portion 511 on the substrate 1 overlaps with at least part of the orthographic projection of the data line 3 on the substrate 1; at least part of orthographic projection of the second sub common line portion 512 on the substrate 1 overlaps with at least part of the orthographic projections of the pixel electrode lapping portion PB on the substrate 1; and a maximum length a1 of the first sub common line portion 511 in the second direction Y is smaller than a maximum length a2 of the second sub common line portion 512 in the second direction Y. In the embodiments of the disclosure, the maximum length a1 of the first sub common line portion 511 in the second direction Y is smaller than the maximum length a2 of the second sub common line portion 512 in the second direction Y, which means that the first common line 51 is narrowed at a position where the first common line 51 intersect with the data line 3 to avoid a large load generated by the data line 3 and affecting signal transmission of the data line 3 due to a large overlap area between the first common line 51 and the data line 3; while the first common line 51 is widen at a position where the first common line 51 overlaps with the pixel electrode lapping portion PB is widen, so that the first common line 51 have a wider region for allowing the electrical connection with the pixel electrode 40 through a via.

In some embodiments, as shown in FIG. 1A and FIG. 1B, the first common line 51 has a first common notch 513, where the first common notch is located on a side of the first common line 51 facing the first gate line 21 and at a position where the first common line overlaps with the data line 3; and the first common line 51 has a second common notch 514, where the second common notch 514 is located on a side of the first common line 51 facing the second gate line 22 and at the position where the first common line 51 overlaps with the data line 3. In this way, the first common line 51 is narrowed at the position intersecting with the data line 3.

In some embodiments, as shown in FIG. 1A and FIG. 1B, a central region of the first common notch 513 does not coincide with a central region of the second common notch 514 to avoid a risk of line breakage caused by the first common line 51 being too refined at the position intersecting with the data line 3.

In some embodiments, as shown in FIG. 1A and FIG. 1B, the first gate line 21 has a first gate notch 211 on a side facing the first common line 51 and at the position intersecting with the data line 3; and the second gate line 2 has second gate notch 221 on a side facing the first common line 51 and at the position intersecting with the data line 3. In this way, the first gate line 21 may be narrowed at the position where the first gate line 21 intersects with the data line 3, and the second gate line 22 may be narrowed at the position where the second gate line 22 intersects with the data line 3 to avoid a case that large overlapping areas between the first gate line 21 and the second gate line 22 with the data line 3, causing a large load generated by the first gate line 21, the second gate line 22 and the data line 3, affecting the signal transmission of the first gate line 21, the second gate line 22 and the data line 3.

In some embodiments, as shown in FIG. 1A and FIG. 1B, the array substrate further includes: second common signal line groups 52 between adjacent gate line groups 2 and extending in the second direction Y. The second common signal line group includes two second common signal lines 520 respectively located on different sides of the data line 3. In some embodiments, as shown in FIG. 1A and FIG. 1B, an orthographic projection of the second common signal line 520 on the substrate 1 overlaps with at least part of the orthographic projection of the pixel electrode 40 on the substrate 1. In this way, a first storage capacitance is formed by the second common signal line 520 and the pixel electrode 40.

In some embodiments, as shown in FIG. 1A and FIG. 1B, the array substrate includes: third common signal lines 53 between the adjacent gate line groups 2 and extending in the second direction Y. At least part of an orthographic projection of the third common signal line 53 on the substrate 1 is located between the orthographic projection of the first pixel electrode 41 on the substrate 1 and the orthographic projection of the second pixel electrode 42 on the substrate 1.

In some embodiments, as shown in FIG. 1A and FIG. 1B, the orthographic projection of the third common signal line 53 on the substrate 1 overlaps with a part of the orthographic projection of the pixel electrode 40 on the substrate 1. In this way, a second storage capacitance is formed by the third common signal line 53 and the pixel electrode 40.

In some embodiments, as shown in FIG. 1A and FIG. 1B, the array substrate includes: fourth common signal lines 54 located between the adjacent gate line groups 2 and extending in the first direction X. An orthographic projection of the fourth common signal line 54 on the substrate 1 passes through a center of the orthographic projection of the pixel electrode 40 on the substrate 1. The orthographic projection of the fourth common signal line 54 on the substrate 1 overlaps with the orthographic projection of the pixel electrode 40 on the substrate 1, thus a third storage capacitance is formed by the fourth common signal line 54 and the pixel electrode 40.

In some embodiments, as shown in FIG. 1A and FIG. 1B, the second common signal line 520 and the third common signal line 53 are both electrically connected with the fourth common signal line 54, between the adjacent gate line groups 2.

In some embodiments, the array substrate further includes: lapping portions in a different layer from the third common signal lines 53. The third common signal lines 53 on both sides of the same gate line group 2 may be electrically connected through the lapping portion. Specifically, the third common signal line 53 and the lapping portion may be electrically connected through a semi-hanging hole. Specifically, there may be a second insulating layer between a layer where the third common signal lines 53 are located and a layer where the lapping portions are located. The second insulating layer may have a second via, and the second via partially exposes the third common signal line 53 and partially exposes the substrate. At the second via, the lapping portion is partially in contact with the third common signal line 53 and partially in contact with the substrate 1, and the two third common signal lines 53 on both sides of gate line group 2 are electrically connected through the integrated lapping portion. In the embodiments of the disclosure, the third common signal line 53 and the lapping portion are electrically connected through the semi-hanging hole, a stepped structure inside the second via can be formed, which can guide the alignment liquid, preventing the alignment liquid from not sticking, improving uniformity of the alignment liquid of the array substrate, and avoiding the appearance of moire patterns in images, thereby improving the display quality.

In some embodiments, the second insulating layer may include at least one or a combination of the gate insulating layer 11, the passivation layer 12, the planarization layer 13, and the color resistor layer 6.

In some embodiments, the lapping portions may be located in the same layer as the pixel electrodes 40.

In some embodiments, in a non-display region, the array substrate may further include: a fifth common line surrounding a display region; at least one of the second common signal line 520, the third common signal line 53, or the fourth common signal line 54 is electrically connected with the fifth common line; and the first common line 51 may be specifically connected with the fifth common line.

In some embodiments, as shown in FIG. 1A and FIG. 1B, a width of the third common signal line 53 in the first direction X is greater than a width of the second common line 520 in the first direction X.

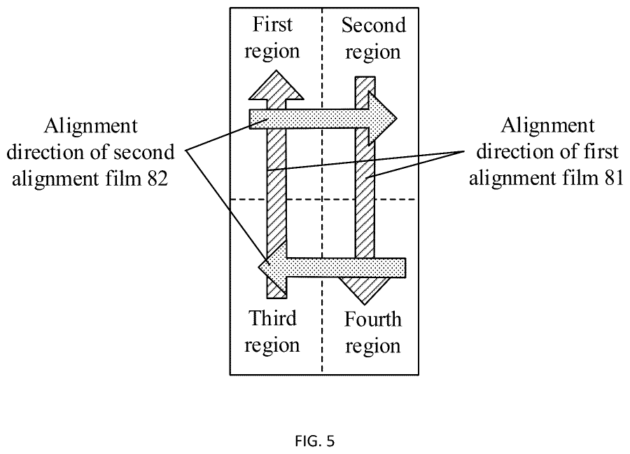

Specifically, as shown in FIG. 4, the first storage capacitance, the second storage capacitance, and the third storage capacitance may constitute a storage capacitor Ccs for driving deflection of a liquid crystal. The second electrode TB of the transistor, and a structure (such as the pixel electrode 40, and the active pattern 8) electrically connected with the second electrode TB of the transistor can form a coupling capacitance Cgs with the gate line 20.

Capacitance Clc may be generated by a liquid crystal between the array substrate and the counter substrate, for driving the deflection of the liquid crystal.

In some embodiments, as shown in FIG. 1A and FIG. 1B, the first common line 51, the second common line 52, the third common line 53, and the fourth common line 54 are of the same layer and material as the gate line 20. In this way, while the gate line 20 is formed, the first common line 51, the second common line 52, the third common line 53, and the fourth common line 54 may be formed to simplify a production process of the array substrate and reduce a production cost of the array substrate.

In some embodiments, as shown in FIG. 1A and FIG. 1E, the array substrate further includes: a first conductive layer 7 located at a side of the data line 3 facing away from the substrate 1. The first conductive layer 7 includes: a plurality of first lines 71 extending in the second direction Y, and a second line 72 electrically connected with the first lines 71 and extending in the first direction X. The second line 72 is disconnected at a position intersecting with the pixel electrode lapping portion PB. At least part of an orthographic projection of the first line 71 on the substrate 1 overlaps with at least part of the orthographic projection of the data line 3 on the substrate 1; and at least part of an orthographic projection of the second line 72 on the substrate 1 overlaps with at least part of the orthographic projection of the gate line 20 on the substrate 1.

In the embodiment of the disclosure, the array substrate further includes: the first conductive layer 7 located at the sides of the data line 3 facing away from the substrate 1. The first conductive layer 7 includes: the plurality of first lines 71 extending in the second direction Y, and the second line 72 electrically connected with the first lines 71 and extending in the first direction X. At least part of the orthographic projection of the first line 71 on the substrate 1 overlaps with at least part of the orthographic projection of the data line 3 on the substrate 1, thereby shielding electric fields on the data line 3 to avoid light leakage, and eliminating the need for arranging the black matrix directly above the data line 3 and increasing the pixel aperture ratio. Moreover, compared to a conventional data line BM-less structure (DBS), the embodiments of the disclosure eliminate the DBS line above the second electrodes TB of the transistors, which can reduce the load on the data line 3 and increase a product charging ratio. At least part of the orthographic projection of the second line 72 on the substrate 1 overlaps with at least part of the orthographic projection of the gate line 20 on the substrate 1, so as to shield signals of the gate line 20 and avoiding light leakage at the gate line 20 of the array substrate. The width of the black matrix directly above the gate line 20 can be reduced to a certain extent, thereby increasing the pixel aperture ratio.

In some embodiments, as shown in FIG. 1I, the orthographic projection of the gate line 20 on the substrate 1 have an overlapping region with the orthographic projection of the second line 72 on the substrate 1, and a minimum distance c1 of the overlapping region in the second direction Y is small (for example, it may be 0.5 μm). When the patterns of the two film layers shift during the manufacturing process, the small distance may cause light leakage at this position. In some embodiments, when forming a patterned black matrix, an overexposure process may be used to increase the width of the black matrix at this position and increase a distance c2 between the outer edge of the gate line 2 and an outer edge of the black matrix.

For example, the distance c2 between the outer edge of the gate line 2 and the outer edge of the black matrix may be greater than or equal to 8.25 μm.

In some embodiments, as shown in FIG. 1A and FIG. 1E, the first conductive layer 7 is located in the same layer as the pixel electrodes 40.

In some embodiments, as shown in FIG. 1A and FIG. 1E, at least part of the orthographic projection of the first line 71 on the substrate 1 overlapping with at least part of the orthographic projection of the data line 3 on the substrate 1, may be that the orthographic projection of the first line 71 on the substrate 1 covers the orthographic projection of the data line 3 on the substrate 1.

In some embodiments, as shown in FIG. 1A and FIG. 1E, the second line 72 includes: a plurality of second line sub portions 720 distributed sequentially in the first direction X. The second line sub portions 720 are electrically connected with the first lines 71. The first conductive layer 7 further includes: third lines 73 extending in the second direction Y. An orthographic projection of the third line 73 on the substrate 1 is located between the orthographic projections of the two pixel electrodes 40 of the pixel electrode groups 4 on the substrate 1. One end of the third line 73 is electrically connected with a second line sub portion 720 at a side of the pixel electrodes 40, and the other end is connected with a second line sub portion 720 at the other side of the pixel electrode 40 and connected with an adjacent first line 71. Specifically, for example, as shown in FIG. 1E, in the first pixel electrode row, one end of the third line 73 is electrically connected with the second line sub portion 720 at an upper side of the third one of pixel electrode 40s (i.e., the first pixel electrode 41) from the left, and the other end is electrically connected with the second line sub portion 720 at a lower side of the second one of pixel electrodes 40 (i.e., the second pixel electrode 42) from the left.

In the embodiment of the disclosure, the first conductive layer 7 further includes: the third lines 73 extending in the second direction Y. One end of the third line 73 is electrically connected with the second line sub portion 720 at one side of the pixel electrode 40, and the other end is connected with the second line sub portion 720 at the other side of the pixel electrode 40 and connected with the adjacent first line 71, so that the first conductive layer 7 in the entire display region may be made to present a special mesh structure, which makes the first conductive layer 7 in the display region have good signal stability.

In some embodiments, as shown in FIG. 1A and FIG. 1E, a width of a part of the first line 71 located between two adjacent pixel electrode bodies PA in the first direction X may be greater than a width of the third line 73 in the first direction X. In some embodiments, as shown in FIG. 1A and FIG. 1E, a width of a part of the first line 71 intersecting with the gate line 2 in the first direction X may be smaller than the width of the part of the first line 71 located between the two adjacent pixel electrode bodies PA in the first direction X.

In some embodiments, as shown in FIG. 1A and FIG. 1E, the orthographic projection of the third line 73 on the substrate 1 do not overlap with the orthographic projection of the pixel electrode lapping portion PB on the substrate 1. In this way, electrical connection between the first conductive layer 7 and the pixel electrodes 40 may be avoided to ensure the normal display of the pixel electrodes 40.

In some embodiments, as shown in FIG. 1A and FIG. 1E, a part of the orthographic projection of the second line 72 on the substrate 1 is located at a gap between the gate line 20 and the pixel electrode 40. In this way, while shielding the signal of the gate line 20 and avoiding light leakage at the gate line 20 of the array substrate, a risk that the second line 72 and the pixel electrode lapping portion PB are electrically connected into a whole because the second line 72 is too close to the pixel electrode lapping portion PB may be avoided.

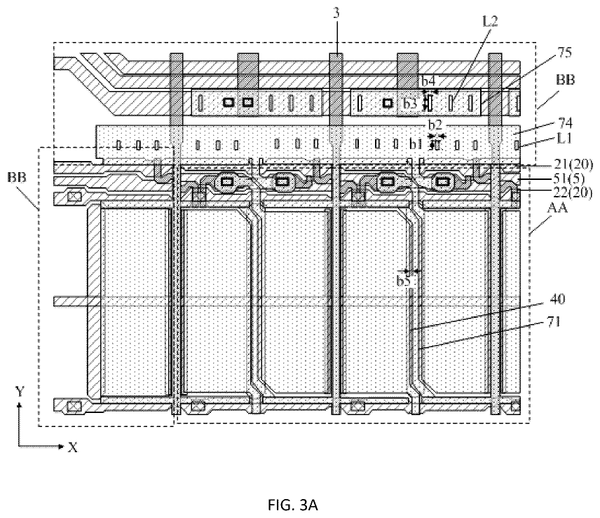

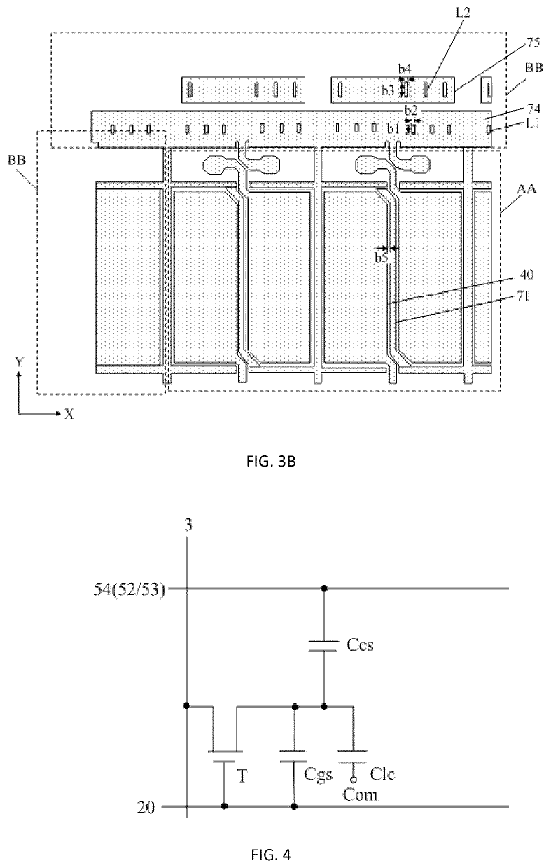

In some embodiments, as shown in FIG. 3A and FIG. 3B, FIG. 3B may be a schematic single-layer diagram of the pixel electrode in FIG. 3A. The array substrate includes a display region AA and a non-display region BB located on a periphery of the display region. The first conductive layer 7 further includes a fourth line 74 located in the non-display region BB and extending in the first direction X, and the fourth line 74 has a plurality of first hollowed-out structures L1.

In the embodiments of the disclosure, on the premise of ensuring that the fourth line 74 is not disconnected, the plurality of first hollowed-out structures L1 are arranged in the fourth line 74 on the periphery on a side without a dummy pixel electrode, and a region with photoresist (PR) accumulation is moved outside the display region AA, thereby avoiding a abnormal display problem of short circuit caused by the connection between different patterns, that is, avoiding a case that the dummy pixel electrodes cannot be arranged when a space on an opposite side of a bonding side of the display panel is limited, compared to the non-display region BB, the spacing between the adjacent pixel electrodes 40 (or between each line of the first conductive layer 7 and the pixel electrode) close to the non-display region BB and located in the display region is small, and abnormal display caused by the short between the patterns due to photoresist (PR) accumulation is prone to occurring.

In some embodiments, as shown in FIG. 3A and FIG. 3B, the first conductive layer 7 further includes a transfer portion 75 located at a side of the fourth line 74 away from the display region, and the transfer portion 75 has a plurality of second hollowed-out structures L2. In the embodiments of the disclosure, the transfer portion 75 also has the plurality of second hollowed-out structures L2, which can further move the region with the PR accumulation outside of the display region AA, and avoids the abnormal display problem due to short caused by the connection between the different patterns.

In some embodiments, as shown in FIG. 3A and FIG. 3B, the transfer portion 75 may serve as an intermediate electrode for jumper of signal lines in different layers, for example, it may be an intermediate electrode for jumper of the lines in the layer of the gate line 20 and the lines of the layer of the data line 3.

In some embodiments, as shown in FIG. 3A and FIG. 3B, a maximum length b1 of the first hollowed-out structure L1 in the second direction Y is greater than a maximum length b2 of the first hollowed-out structure in the first direction X; and a maximum length b3 of the second hollowed-out structure L2 in the second direction Y is greater than a maximum length b4 of the second hollowed-out structure in the first direction X. In the embodiments of the disclosure, the maximum length b1 of the first hollowed-out structure L1 in the second direction Y is greater than the maximum length b2 of the first hollowed-out structure in the first direction X, and the maximum length b3 of the second hollowed-out structure L2 in the second direction Y is greater than the maximum length b4 of the second hollowed-out structure in the first direction X, that is, the long edge directions of the first hollowed-out structure L1 and the second hollowed-out structure L2 are the same as long direction of the pixel electrode 40.

When patterning, it is beneficial for the distribution uniformity of the photoresist in the long direction of the pixel electrodes 40, thereby avoiding the problem of abnormal display caused by the short between the patterns due to the photoresist (PR) accumulation.

In some embodiments, as shown in FIG. 3A and FIG. 3B, the maximum length b2 of the first hollowed-out structure L1 in the first direction X is smaller than or equal to a minimum spacing b5 between the pixel electrode 40 and the first line 71 in the first direction X; and the maximum length b4 of the second hollowed-out structure L2 in the first direction X is smaller than or equal to a minimum spacing b5 between the pixel electrode 40 and the first line 71 in the first direction X. In this way, the position of photoresist accumulation may be transferred from an interior of the display region to an exterior of the display region.

In some embodiments, a material of the active pattern 8 may include: amorphous silicon, low-temperature polycrystalline silicon, or a metal oxide semiconductor, etc. A material of the metal oxide semiconductor may include: an amorphous indium gallium zinc oxide (a-IGZO) material, zinc oxynitride (ZnON), or any one or more of indium zinc tin oxide (IZTO), indium gallium zinc oxide (IGZO), indium gallium oxide (IGO), indium gallium zinc tin oxide (IGZTO), indium zinc oxide (IZO), or a rare earth element-doped metal oxide (RE-OS), where, the rare earth element-doped metal oxide may include a lanthanide-doped metal oxide (Ln-OS). A crystalline state of the material of the active layer may be amorphous, partially crystalline, or polycrystalline. The material of the active pattern 8 is the rare earth element-doped metal oxides, even when exposed to light, the active pattern 8 may have stable performance, which can further increase the aperture ratio of the display panel without the need for arranging the light-blocking layer in a light transmittance region.

In some embodiments, the first conductive layer 7 may be in the same layer and of the same material as the pixel electrode 40.

In some embodiments, the material of the pixel electrode 40 may include: metal oxides, such as an indium tin oxide, an indium-doped zinc oxide (AZO), a fluorine-doped tin oxide (AZO), an aluminum-doped zinc oxide (AZO), and an indium-doped cadmium oxide.

In some embodiments, the material of the first conductive layer 7 may include: metal oxides, such as an indium tin oxide, an indium-doped zinc oxide (AZO), a fluorine-doped tin oxide (AZO), an aluminum-doped zinc oxide (AZO), and an indium-doped cadmium oxide.

In some embodiments, the material of the data lines 3 may include any one or more of silver (Ag), copper (Cu), aluminum (Al), titanium (Ti) and molybdenum (Mo), or alloy materials of the above metals, such as an aluminum-neodymium alloy (AlNd) or a molybdenum-niobium alloy (MoNb), and may be a single-layer structure, or a multi-layer composite structure, such as Ti/Al/Ti.

In some embodiments, the first common lines 51, the second common lines 52, the third common lines 53, and the fourth common lines 54 are of the same layer and material as the gate lines 20.

In some embodiments, the material of the gate line 20 may include any one or more of silver (Ag), copper (Cu), aluminum (Al), titanium (Ti) and molybdenum (Mo), or alloy materials of the above metals, such as an aluminum-neodymium alloy (AlNd) or a molybdenum-niobium alloy (MoNb), and may be a single-layer structure, or a multi-layer composite structure, such as Ti/Al/Ti.

In some embodiments, the materials of the first common line 51, the second common lines 52, the third common lines 53, and the fourth common lines 54 may include any one or more of silver (Ag), copper (Cu), aluminum (Al), titanium (Ti) and molybdenum (Mo), or alloy materials of the above metals, such as an aluminum-neodymium alloy (AlNd) or a molybdenum-niobium alloy (MoNb), and may be a single-layer structure, or a multi-layer composite structure, such as Ti/Al/Ti.

In some examples, the substrate 1 may be a flexible substrate or a rigid substrate. For example, the rigid substrate may include a glass substrate. The flexible substrate may include a first flexible material layer, a first inorganic material layer, a semiconductor layer, a second flexible material layer and a second inorganic material layer which are stacked. Materials of the first flexible material layer and the second flexible material layer may adopt polyimide (PI), polyethylene terephthalate (PET) or surface-treated soft polymer film and other materials, materials of the first inorganic material layer and the second inorganic material layer may adopt silicon nitride (SiNx) or silicon oxide (SiOx) and the like, which are configured to improve water and oxygen resistance of the substrate, and the material of the semiconductor layer may adopt amorphous silicon (a-Si), which are not limited here.

Based on the same inventive conception, embodiments of the disclosure further provide a display panel, including the array substrate as provided in the embodiments of the disclosure, and further including: a counter substrate arranged opposite to the array substrate, where the counter substrate is provided with a common electrode layer.

In some embodiments, a liquid crystal layer may be arranged between the array substrate and the counter substrate. The liquid crystal layer has a plurality of liquid crystal regions in a region where the pixel electrode 40 is located, and orientations of the liquid crystal layers in different liquid crystal regions are different in an initial state. Specifically, as shown in FIG. 5, for example, the liquid crystal layer has four liquid crystal regions in the region where the pixel electrode 40 is located, and orthographic projections of the four liquid crystal regions on the substrate 1 may be respectively located in a first region and a second region which are on one side of the orthographic projection of fourth common signal line 54 on the substrate 1, and a third region and a fourth region which are on the other side of the orthographic projection of the fourth common signal line 54 on the substrate 1. Specifically, the array substrate may further have a first alignment film layer 81, and the counter substrate may be provided with a second alignment film layer 82. Orientations of the first alignment film layer 81 and the second alignment film layer 82 in different regions may be as shown in FIG. 5, and the orientation of the first alignment film layer 81 may be perpendicular to the orientation of the second alignment film layer 82.

Specifically, the initial state of the liquid crystal layers in different liquid crystal regions may be understood as a deflection state of the liquid crystal layers in different liquid crystal regions when no electric field is applied, that is, a state when no voltage is applied between the pixel electrode 40 and the common electrode layer.

In some embodiments, the common electrode layer of the counter substrate transmits the same common signal as first common lines 51, second common lines 52, third common lines 53, and fourth common lines 54 arranged on the array substrate. Optionally, signals on the first common lines 51, the second common lines 52, the third common lines 53, and the fourth common lines 54 may be different from that on the common electrode layer of the counter substrate.

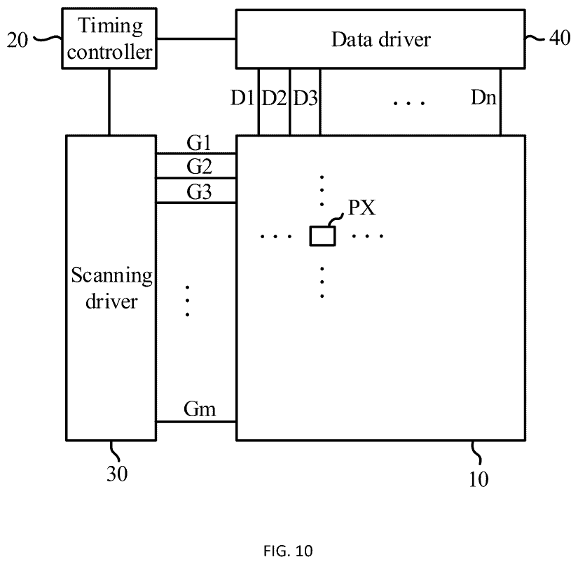

FIG. 10 is a schematic structural diagram of a display panel provided in at least one embodiment of the disclosure. In some examples, as shown in FIG. 10, the display panel may include: a timing controller 20, a data driver 40, a gate drive circuit, and a sub-pixel array 10. The gate drive circuit may include at least one driver, such as a scanning driver 30. The timing controller 20, the data driver 40, and the gate drive circuit may be located in a non-display region on a periphery of a display region of the display panel. The sub-pixel array 10 located in the display region may include a plurality of regularly arranged sub-pixels PX. The scanning driver 30 may be configured to provide scanning signals to the sub-pixels PX along scanning lines; the data driver 40 may be configured to provide data signals to the sub-pixels PX along data lines; and the timing controller 20 may be configured to control the scanning driver 30 and the data driver 40.

In some examples, the timing controller 20 may provide a grayscale value and a control signal fitting the specification of the data driver 40 to the data driver 40; and the timing controller 20 may provide a clock signal, an initial signal, and the like which fit the specification of the scanning driver 30 to the scanning driver 30. The data driver 40 may utilize the grayscale value and the control signal received from the timing controller 20 to generate a data voltage that will be provided to the data lines D1 to Dn. For example, the data driver 40 may use a clock signal to sample the grayscale value and apply a data signal corresponding to the grayscale value to the data lines D1 to Dn in units of sub-pixel rows. The scanning driver 30 may generate scanning signals to be provided to scanning lines G1 to Gm through the clock signal, the initial signal, and the like received from the timing controller 20. For example, the scanning driver 30 may sequentially provide the scanning signals with turn-on pulses to the scanning lines. In some examples, the scanning driver 30 may include a shift register, and may generate the scanning signals under control of the clock signals in a mode of sequentially transmitting scanning initial signals in a form of the turn-on pulses to the next stage of circuit. Both n and m are natural numbers.

In some examples, the gate drive circuit may be directly arranged on the base substrate. For example, gate drivers may be arranged in peripheral regions on left and right sides of the display region. In some examples, the gate drivers may be formed together with the sub-pixels in a process of forming the sub-pixels. However, the embodiments do not limit the positions or formation mode of the gate drivers. In some examples, the gate drivers may be arranged on a separate chip or printed circuit board to be connected to a bonding pad or a bonding pin formed on the base substrate.

In some examples, the data driver 40 may be arranged on a separate chip or printed circuit board to be connected to the sub-pixels PX through signal access pins arranged on the base substrate. For example, the data driver 40 may use formation setting such as a glass on chip, a plastic on chip, and a film on chip, so as to be connected with the signal access pins on the base substrate. The timing controller 20 can be set separately from the data driver 40 or integrated with the data driver 40, which is not limited here.

Based on the same inventive conception, embodiments of the disclosure further provide a display device, including the display panel provided by the embodiments of the disclosure. Implementation of the display device may refer to embodiments of the above display panel, and repetitions are omitted.

In some embodiments, the display panel provided by the embodiments of the disclosure may be a curved display panel. In some embodiments, the display device provided by the embodiments of the disclosure may be a curved display device.

During specific implementation, in the embodiments of the disclosure, the display device may be: any product or component with a display function, such as a mobile phone, a tablet computer, a television, a displayer, a notebook computer, a digital photo frame, and a navigator. It should be understood by those ordinarily skilled in the art that the display device should have other essential constituent parts, which is not repeated here and should not be regarded as limitation to the disclosure.

Based on the same inventive conception, embodiments of the disclosure further provide a method of repairing the array substrate as provided in the embodiments of the disclosure, as shown in FIG. 9, including:

S100, detecting the array substrate is detected; and S200, based on determining that a pixel emits light abnormally, electrically connecting a transistor electrically connected with a pixel electrode in the pixel to the first common line.

In some embodiments, for S200, electrically connecting the transistor electrically connected with the pixel electrode in the pixel to the first common line includes:

electrically connecting a second electrode of the transistor to the first common line at a position where a first via is located.

In the embodiments of the disclosure, the part of the orthographic projection of the second electrode TB of the transistor on the substrate 1 is located between the orthographic projections of the two gate lines 20 of the same gate group 2 on the substrate 1, the orthographic projection of the first common line 51 on the substrate 1 is located between the orthographic projections of the two gate lines 20 of the same gate group 2 on the substrate 1, and at least part of the orthographic projection of the first common line 51 on the substrate 1 overlaps with at least part of the orthographic projection of the second electrode TB of the transistor on the substrate 1. Therefore, in the weakening process, the second electrode TB of the transistor and the first common line 51 may be connected, and the connection via may be located between the orthographic projections of the two gate lines 20 on the substrate 1. Since the light-blocking layer (such as a black matrix) is usually arranged on the two gate lines 20 and a region between the two gate lines 20, it is possible to hide the weakening via in the region where the light-blocking layer is located, thereby solving the problems of transmittance loss caused by the low pixel aperture ratio in Dual Gate structure and contrast reduction caused by metallic reflection in an opening region. Moreover, compared to the conventional array substrate with the common lines respectively arranged on both sides of the gate line group 2, the embodiments of the disclosure can further reduce one common line, reduce the width of the light-blocking layer (such as the black matrix), and have the more significant effect on increasing the aperture ratio. In addition, compared to the conventional array substrate which usually has the quality and yield problem affected by abnormal display caused by non-stick alignment liquid at the via, in the embodiments of the disclosure, the first via K1 is located in the region where the light-blocking layer (such as the black matrix) is located, and the abnormal display region is effectively blocked by the light-blocking layer (such as the black matrix), which can increase the margin width of the alignment liquid coating process and reduce the process difficulty.

It needs to be noted that in the disclosure, the “same layer” refers to a layer structure formed by a single patterning process utilizing the same mask after manufacturing a film used for a certain pattern by a same film forming process. That is, the single patterning process corresponds to one mask (also called a photomask). According to the different specific graphics, the single patterning process may include a plurality of exposure, developing or etching processes, while the specific graphics in the formed layer structure may be continuous or discontinuous, and these specific graphics may be at the different heights or have the different thicknesses.

Although the preferred embodiments of the disclosure have been described, those skilled in the art can make additional modifications and variations on these embodiments once they know the basic creative concept. Therefore, the appended claim intends to be explained as including the preferred embodiments and all modifications and variations falling within the scope of the disclosure.

Apparently, those skilled in the art can make various modifications and variations to the embodiments of the disclosure without departing from the spirit and scope of the embodiment of the disclosure. In this way, if these modifications and variations of the embodiments of the disclosure fall within the scope of the claims of the disclosure and their

What is claimed is:

1. An array substrate, comprising:
a substrate;
a plurality of gate line groups, disposed on a side of the substrate and extending in a first direction, wherein each gate line group comprises two gate lines extending in the first direction;
a plurality of data lines extending in a second direction, wherein the second direction intersects with the first direction;
a plurality of transistors, wherein each transistor comprises: a first electrode electrically connected with the data line, and a second electrode; wherein a part of an orthographic projection of the second electrode of the transistor on the substrate is located between orthographic projections of two gate lines of a same gate group on the substrate;
a plurality of pixel electrode groups, wherein an orthographic projection of at least a part of the pixel electrode group on the substrate is located in a region formed due to intersection of the gate line groups and the data lines; and each pixel electrode group comprises: two pixel electrodes distributed in the first direction; and
a plurality of first common lines, wherein an orthographic projection of the first common line on the substrate is located between the orthographic projections of the two gate lines of the same gate line group on the substrate, and at least part of the orthographic projection of the first common line on the substrate overlaps with at least part of the orthographic projection of the second electrode of the transistor on the substrate.

2. The array substrate according to claim 1, wherein the pixel electrode comprises a pixel electrode body and a pixel electrode lapping portion extending from an end of the pixel electrode body; wherein a part of an orthographic projection of the pixel electrode lapping portion on the substrate is located between the orthographic projections of the two gate lines of the same gate line group on the substrate; and
the part of the orthographic projection of the pixel electrode lapping portion on the substrate overlaps with at least part of the orthographic projection of the second electrode of the transistor on the substrate.

3. The array substrate according to claim 1, wherein the pixel electrode lapping portion comprises: a first sub-lapping portion extending in the second direction and a second sub-lapping portion extending in the first direction; one end of the first sub-lapping portion is electrically connected with the pixel electrode body, and the other end of the first sub-lapping portion is electrically connected with the second sub-lapping portion; and
an orthographic projection of the second sub-lapping portion on the substrate is located between the orthographic projections of the two gate lines of the same gate line group on the substrate.

4. The array substrate according to claim 3, wherein the two pixel electrodes of a same pixel electrode group are electrically connected with a same data line through the transistor; and
in the same pixel electrode group, second sub-lapping portions of the two pixel electrodes extend from corresponding first sub-lapping portions towards a side of the same data line electrically connected with the two pixel electrodes.

5. The array substrate according to claim 4, wherein two second sub-lapping portions of two pixel electrodes adjacent in the second direction extend in opposite directions from the corresponding first sub-lapping portions.

6. The array substrate according to claim 3, wherein
at least two second sub-lapping portions adjacent to each other in the first direction have at least parts symmetrical to each other with respect to a first axis;
wherein the first axis is located between the adjacent pixel electrodes and extending in the second direction.

7. The array substrate according to claim 6, wherein the plurality of transistors comprise: first transistors and second transistors; in the same pixel electrode group, one of the pixel electrodes is electrically connected with the data line through the first transistor, and the other one of the pixel electrodes is electrically connected with the data line through the second transistor; and
for the first transistor and the second transistor which are electrically connected with the same pixel electrode group, a second electrode of the first transistor and a second electrode of the second transistor are symmetrical with respect to a second axis;
wherein the second axis passes through a center of the pixel electrode and extending in the first direction

8. The array substrate according to claim 7, wherein for the first transistor and the second transistor which are electrically connected with the same pixel electrode group, the second electrode of the first transistor and the second electrode of the second transistor are both located between the first axis and the data line electrically connected with the two pixel electrodes;
wherein, two second electrodes which are at least partially adjacent in the second direction are symmetrical with respect to the second axis;
wherein the second electrode of the transistor comprises: a first portions extending in the second direction, and a second portion connected with the first portion and extending in the first direction; and
first portions of two second electrodes which are at least partially adjacent in the second direction both extend from corresponding second portions towards a side of a pixel electrode body electrically connected with the transistors.

9. (canceled)

10. (canceled)

11. The array substrate according to claim 8, wherein first portions of two second electrodes which are at least partially adjacent in the first direction extend in opposite directions from corresponding second portions;
second portions of two second electrodes which are at least partially adjacent in the first direction are symmetrical with respect to the first axis;
wherein the transistor further comprises: an active pattern; wherein the active pattern comprises: a first active outer edge and a second active outer edge extending in the second direction; in a same transistor, an orthographic projection of the second active outer edge on the substrate is located on a side of the first active outer edge away from the data line connected with the transistor;
the first electrode of the transistor comprises: a first portion extending in the second direction, and a second portion for connecting the first portion with the data line; and
at least part of the orthographic projection of the first active outer edge on the substrate coincides with at least part of an orthographic projection of an outer edge of the first portion of the first electrode at a side of the first portion of the first electrode away from the first portion of the second electrode on the substrate; and at least part of the orthographic projection of the second active outer edge on the substrate coincides with at least part of an orthographic projection of an outer edge of the first portion of the second electrode at a side of the first portion of the second electrode away from the first portion of the first electrode on the substrate.

12. (canceled)

13. (canceled)

14. The array substrate according to claim 2, further comprising: a first insulating layer between a layer where the pixel electrode groups are located and a layer where second electrodes of the transistors are located; wherein
the first insulating layer comprises first vias, and the pixel electrode lapping portions are electrically connected with the second electrodes of the transistors through the first vias.

15. The array substrate according to claim 14, wherein at least part of an orthographic projection of the first common line on the substrate overlaps with at least part of an orthographic projection of the first via on the substrate.

16. The array substrate according to claim 14 further comprising: a color resistor layer located at a side of a layer where the pixel electrodes are located facing the substrate;
wherein the first insulating layer comprises the color resistor layer.

17. The array substrate according to claim 16, further comprising: a plurality of first spacers and a plurality of second spacers;
wherein a length of the first spacer in a direction perpendicular to the substrate is greater than a length of the second spacer in the direction perpendicular to the substrate; and
a shape of an orthographic projection of the first spacer on the substrate is different from a shape of an orthographic projection of the second spacer on the substrate;
wherein a maximum length of the second spacer in the second direction is greater than a maximum length of the first spacer in the second direction; or wherein a distribution density of the second spacers is greater than a distribution density of the first spacers.

18. (canceled)

19. (canceled)

20. The array substrate according to claim 2, wherein the first common line comprises: a first sub common line portion and a second sub common trace portion arranged in the first direction; at least part of an orthographic projection of the first sub common line portion on the substrate overlaps with at least part of the orthographic projection of the data line on the substrate; at least part of orthographic projection of the second sub common line portion on the substrate overlaps with at least part of the orthographic projection of the pixel electrode lapping portion on the substrate; and
a maximum length of the first sub common line portion in the second direction is smaller than a maximum length of the second sub common line portion in the second direction.

21. The array substrate according to claim 2, further comprising: a first conductive layer located at a side of the data lines facing away from the substrate; wherein
the first conductive layer comprises: a plurality of first lines extending in the second direction, and a second line electrically connected with the first lines and extending in the first direction; the second line is disconnected at a position intersecting with the pixel electrode lapping portion; and
at least part of an orthographic projection of the first line on the substrate overlaps with at least part of the orthographic projection of the data line on the substrate, and at least part of an orthographic projection of the second line on the substrate overlaps with at least part of the orthographic projection of the gate line on the substrate.

22. The array substrate according to claim 21, wherein the second line comprises: a plurality of second line sub portions distributed sequentially in the first direction; the second line sub portions are electrically connected with the first lines; and the first conductive layer further comprises: third lines extending in the second direction; and
an orthographic projection of the third line on the substrate is located between orthographic projections of the two pixel electrodes of the pixel electrode group on the substrate; and one end of the third line is electrically connected with the second line sub portion on one side of the pixel electrode, and the other end of the third line is connected with the second trace sub portion on the other side of the pixel electrode and connected with an adjacent first line;
wherein the orthographic projection of the third line on the substrate does not overlap with the orthographic projection of the pixel electrode lapping portion on the substrate;
wherein a part of the orthographic projection of the second line on the substrate is located at a gap between the gate line and the pixel electrode.

23. (canceled)

24. (canceled)

25. The array substrate according to claim 21, comprising: a display region and a non-display region located on a periphery of the display region;
wherein the first conductive layer further comprises a fourth line located in the non-display region and extending in the first direction, and the fourth line has a plurality of first hollowed-out structures.

26. The array substrate according to claim 25, wherein the first conductive layer further comprises a transfer portion located on a side of the fourth line away from the display region, and the transfer portion comprises a plurality of second hollowed-out structures;
wherein a maximum length of the first hollowed-out structure in the second direction is greater than a maximum length of the first hollowed-out structure in the first direction; and
a maximum length of the second hollowed-out structure in the second direction is greater than a maximum length of the second hollowed-out structure in the first direction;
wherein the maximum length of the first hollowed-out structure in the first direction is smaller than or equal to a minimum spacing between the pixel electrode and the first line in the first direction; and
the maximum length of the second hollowed-out structure in the first direction is smaller than or equal to the minimum spacing between the pixel electrode and the first line in the first direction.

27. (canceled)

28. (canceled)

29. The array substrate according to claim 21, wherein the first conductive layer is a same layer as the pixel electrodes.

30. A display panel, comprising the array substrate according to claim 1, and further comprising: a counter substrate opposite to the array substrate, wherein the counter substrate is provided with a common electrode layer.

31. (canceled)

32. (canceled)

33. (canceled)
